(19) United States
(12) Patent Application Publication
(10) Pub. No.: US 2024/0347529 A1
(43) Pub. Date: Oct. 17, 2024

(54) PROTECTION CIRCUIT AND SEMICONDUCTOR DEVICE

(71) Applicant: SONY SEMICONDUCTOR SOLUTIONS CORPORATION, KANAGAWA (JP)

(72) Inventors: TOMOYA NISHIDA, KUMAMOTO (JP); YOSHIKAZU MOTOYAMA, KUMAMOTO (JP); HIDEAKI FUTAI, KUMAMOTO (JP)

(21) Appl. No.: 18/574,986

(22) PCT Filed: Feb. 15, 2022
(86) PCT No.: PCT/JP2022/005953

§ 371 Date: Dec. 28, 2023

(30) Foreign Application Priority Data
Jul. 9, 2021 (JP) 2021-114604

(51) Int. Cl. H01L 27/02; H01L 27/088; H01L 29/778; H03F 1/52; H03F 3/195; H03F 3/24

(52) U.S. Cl. CPC H01L 27/0266; H01L 27/0883; H01L 29/7786; H03F 1/523; H03F 3/195; H03F 3/245; H03F 2200/451

(57) ABSTRACT

A protection circuit includes a first insulated gate field-effect transistor in which: a first main electrode is coupled between an external terminal and an internal circuit; a second main electrode and a gate electrode are coupled to a reference power supply; and an electric charge accumulation section configured to accumulate hot carriers is provided in a gate insulating film.

### TECHNICAL FIELD

The present disclosure relates to a protection circuit and a semiconductor device.

### BACKGROUND ART

Patent Literature 1 discloses a radio frequency integrated circuit with an electrostatic protection element. The electrostatic protection element electrically couples a depletion-type field-effect transistor and an enhancement-type field-effect transistor in series to each other, and further electrically couples a capacitor to the enhancement-type field-effect transistor in parallel. The field-effect transistors each include a MESFET, a gate junction type FET, a HEMT, or the like.

In the electrostatic protection element, when a noise or a high-voltage pulse is inputted from outside, the enhancement-type field-effect transistor performs a breakdown operation and an impedance thereof is lowered to allow for discharging of the noise or the high-voltage pulse.

Further, Patent Literature 2 discloses a surge protection element and a semiconductor device. The surge protection element includes a pnp bipolar transistor. The bipolar transistor is configured with a p-type GaN layer as a collector region, an AlGaN layer and a Gan layer as a base region, and a p-type Gan layer as an emitter region. In the surge protection element, a surge is absorbed as a puchthrough current.

Furthermore, Patent Literature 3 discloses a semiconductor integrated circuit including an electrostatic breakdown protection circuit. The electrostatic breakdown protection circuit includes a diode-coupled transistor. A bipolar transistor or a MOSFET is used as the transistor.

### CITATION LIST

### Patent Literature

Patent Literature 1: Japanese Patent No. 4843927

Patent Literature 2: International Publication No. WO2014/103126A1

Patent Literature 3: Japanese Patent No. 4803747

### SUMMARY OF THE INVENTION

A radio frequency power amplifier operating in a millimeter wave band has been developed for next-generation mobile terminals. An insulated gate field-effect transistor including a GAN-based wide band gap material is used to construct the radio frequency power amplifier. Specifically, a metal-insulator-semiconductor field-effect transistor (Metal Insulator Semiconductor Field Effect Transistor; hereinafter simply referred to as a “MISFET”) is used.

The electrostatic protection element disclosed in Patent Literature 1 described above, the surge protection element disclosed in Patent Literature 2, and the electrostatic breakdown protection circuit disclosed in Patent Literature 3 each use a p-type layer. In a GaN-based process, p-type impurities are very low in activation rate, which makes it difficult to produce p-type GaN and makes its process affinity (mass productivity) in a manufacturing process poor. In other words, it is difficult to implement a protection element using p-type GaN. Accordingly, a protection circuit and a semiconductor device that are superior in electrostatic discharge (Electro Static Discharge: hereinafter simply referred to as “ESD”) robustness or avalanche (Avalanche) robustness are desired.

The present technology provides a protection circuit and a semiconductor device that are superior in ESD robustness or avalanche robustness.

A protection circuit according to a first embodiment of the present disclosure includes a first insulated gate field-effect transistor in which: a first main electrode is coupled between an external terminal and an internal circuit; a second main electrode and a gate electrode are coupled to a reference power supply: and an electric charge accumulation section configured to accumulate hot carriers is provided in a gate insulating film.

A semiconductor device according to a second embodiment of the present disclosure includes an external terminal provided on a substrate, an internal circuit provided on the substrate and coupled to the external terminal, and a protection circuit provided on the substrate and including a fist insulated gate field-effect transistor in which: a first main electrode is coupled between the external terminal and the internal circuit; a second main electrode and a gate electrode are coupled to a reference power supply: and an electric charge accumulation section configured to accumulate hot carriers is provided in a gate insulating film.

### BRIEF DESCRIPTION OF DRAWINGS

FIG. 1 is a layout diagram (a plan view) of a radio frequency power amplifier module equipped with a semiconductor device that incorporates a protection circuit and an internal circuit according to a first embodiment of the present disclosure.

FIG. 2 is a circuit block diagram of the protection circuit and the internal circuit of the semiconductor device illustrated in FIG. 1.

FIG. 3 is a main-part cross-sectional view (a cross-sectional view taken along line A-A illustrated in FIG. 4) of the semiconductor device describing a cross- sectional structure of MISFETs constructing the protection circuit and the internal circuit illustrated in FIGS. 1 and 2.

FIG. 4 is a main-part plan view of the semiconductor device describing a plan structure of the MISFETs constructing the protection circuit and the internal circuit illustrated in FIGS. 1 and 2.

FIG. 5 is a first process cross-sectional diagram corresponding to FIG. 3 and describing a method of manufacturing the semiconductor device incorporating the protection circuit and the internal circuit according to the first embodiment.

FIG. 6 is a second process cross-sectional diagram describing the method of manufacturing the semiconductor device.

FIG. 7 is a third process cross-sectional diagram describing the method of manufacturing the semiconductor device.

FIG. 8 is a fourth process cross-sectional diagram describing the method of manufacturing the semiconductor device.

FIG. 9 is a fifth process cross-sectional diagram describing the method of manufacturing the semiconductor device.

FIG. 10 is a sixth process cross-sectional diagram describing the method of manufacturing the semiconductor device.

FIG. 11 is a seventh process cross-sectional diagram describing the method of manufacturing the semiconductor device.

FIG. 12 is an eighth process cross-sectional diagram describing the method of manufacturing the semiconductor device.

FIG. 13 is a flowchart describing a method of adjusting a threshold voltage of the protection circuit illustrated in FIGS. 2 to 4.

FIG. 14 is a timing chart describing the method of adjusting the threshold voltage of the protection circuit based on the flowchart illustrated in FIG. 13.

FIG. 15 is a main-part cross-sectional view of the semiconductor device corresponding to FIG. 3 and describing a cross-sectional structure of MISFETs constructing a protection circuit and an internal circuit according to a second embodiment of the present disclosure.

FIG. 16 is a circuit block diagram of the protection circuit and the internal circuit corresponding to FIG. 2 in a semiconductor device according to a third embodiment of the present disclosure.

FIG. 17 is a circuit block diagram of the protection circuit and the internal circuit corresponding to FIG. 2 in a semiconductor device according to a fourth embodiment of the present disclosure.

FIG. 18 is a circuit block diagram of the protection circuit and the internal circuit corresponding to FIG. 2 in a semiconductor device according to a fifth embodiment of the present disclosure.

FIG. 19 is a circuit block diagram of the protection circuit and the internal circuit corresponding to FIG. 2 in a semiconductor device according to a sixth embodiment of the present disclosure.

FIG. 20 is a circuit block diagram of the protection circuit and the internal circuit corresponding to FIG. 2 in a semiconductor device according to a seventh embodiment of the present disclosure.

FIG. 21 is a circuit block diagram of the protection circuit and the internal circuit corresponding to FIG. 2 in a semiconductor device according to an eighth embodiment of the present disclosure.

FIG. 22 is a circuit block diagram of the protection circuit and the internal circuit corresponding to FIG. 2 in a semiconductor device according to a ninth embodiment of the present disclosure.

FIG. 23 is a circuit block diagram of the protection circuit and the internal circuit corresponding to FIG. 2 in a semiconductor device according to a tenth embodiment of the present disclosure.

FIG. 24 is a circuit block diagram of the protection circuit and the internal circuit corresponding to FIG. 2 in a semiconductor device according to an eleventh embodiment of the present disclosure.

FIG. 25 is a circuit block diagram of the protection circuit and the internal circuit corresponding to FIG. 2 in a semiconductor device according to a twelfth embodiment of the present disclosure.

### MODES FOR CARRYING OUT THE INVENTION

Some embodiments of the present disclosure are described in detail below with reference to the drawings. It is to be noted that description is given in the following order.

### 1. First Embodiment

A first embodiment describes a first example in which the present technology is applied to a radio frequency (Radio Frequency: hereinafter simply referred to as “RF”) power amplifier module equipped with a semiconductor device incorporating a protection circuit and an internal circuit. Here, a description is given of a configuration of the RF power amplifier module, a layout of the semiconductor device, a circuit block configuration, a vertical cross-sectional structure, a plan structure, and a manufacturing method of the protection circuit and the internal circuit, and a method of adjusting a threshold voltage of the protection circuit.

### 2. Second Embodiment

A second embodiment describes a second example in which the configuration of the protection circuit is changed in the semiconductor device according to the first embodiment.

### 3. Third Embodiment

A third embodiment describes a third example in which the configuration of the protection circuit is changed in the semiconductor device according to the first embodiment.

### 4. Fourth Embodiment

A fourth embodiment describes a fourth example in which the configuration of the protection circuit is changed in the semiconductor device according to the first embodiment.

### 5. Fifth Embodiment

A fifth embodiment describes a fifth example in which the semiconductor device according to the third embodiment and the semiconductor device according to the fourth embodiment are combined.

### 6. Sixth Embodiment

A sixth embodiment describes a sixth example in which the configuration of the protection circuit is changed in the semiconductor device according to the fourth embodiment.

### 7. Seventh Embodiment

A seventh embodiment describes a seventh example in which the semiconductor device according to the fifth embodiment and the semiconductor device according to the sixth embodiment are combined.

### 8. Eighth Embodiment

An eighth embodiment describes an eighth example in which the configuration of the protection circuit is changed in the semiconductor device according to the sixth embodiment.

### 9. Ninth Embodiment

A ninth embodiment describes a ninth example in which the semiconductor device according to the seventh embodiment and the semiconductor device according to the eighth embodiment are combined.

### 10. Tenth Embodiment

A tenth embodiment describes a tenth example in which the configuration of the protection circuit is changed in the semiconductor device according to the eighth embodiment.

### 11. Eleventh Embodiment

An eleventh embodiment describes an eleventh example in which the semiconductor device according to the ninth embodiment and the semiconductor device according to the tenth embodiment are combined.

### 12. Twelfth Embodiment

A twelfth embodiment describes a twelfth example in which the configuration of the protection circuit is changed in the semiconductor device according to the first embodiment.

### 13. Other Embodiments

### 1. First Embodiment

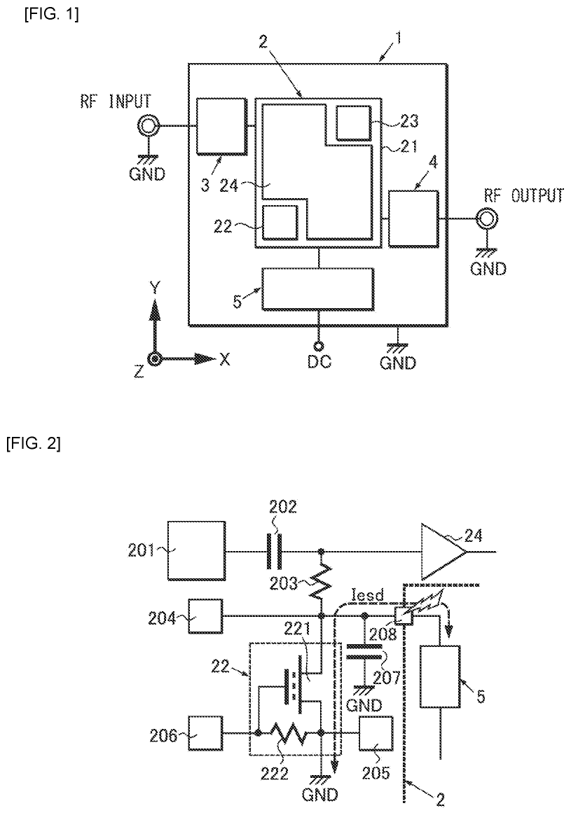

A description will be given of a protection circuit 22, a protection circuit 23, and a semiconductor device 2 according to the first embodiment of the present disclosure with reference to FIGS. 1 to 14.

Here, an arrow-X direction illustrated as appropriate in the drawings indicates one planar direction of the semiconductor device 2 placed on a plane for convenience An arrow-Y direction indicates another planar direction orthogonal to the arrow-X direction. Further, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each illustrated to aid understanding of descriptions, and are not intended to limit directions used in the present technology.

### [Configuration of Protection Circuit 22 and Semiconductor Device 2]

### (1) Planar Layout Configuration of RF Power Amplifier Module 1

FIG. 1 illustrates a planar layout of an RF power amplifier module 1. The RF power amplifier module 1 includes an input section matching circuit 3, the semiconductor device 2, an output section matching circuit 4, and a direct current (Direct Current: hereinafter simply referred to as “DC”) bias circuit 5. The input section matching circuit 3, etc. are mounted on a substrate 10. For example, solders are used for mounting.

The substrate 10 is formed as a module substrate. The substrate 10 is formed in a rectangular shape, for example, as viewed in the arrow-Z direction (hereinafter simply referred to as “in a plan view”).

Here, the input section matching circuit 3 is mounted on a left side on top of the substrate 10. The input section matching circuit 3 is to receive an RF signal from outside the RF power amplifier module 1.

The semiconductor device 2 is mounted on a middle of the substrate 10. The semiconductor device 2 includes the protection circuit 22, an internal circuit 24, and the protection circuit 23.

The protection circuit 22 is configured as an input-side protection circuit. The protection circuit 22 is coupled to each of the input section matching circuit 3 and the internal circuit 24.

In the first embodiment, the internal circuit 24 includes an RF power amplifier. For example, the internal circuit 24 includes an RF power amplifier that operates in a millimeter wave band for a fifth or subsequent generation mobile terminal.

The protection circuit 23 is configured as an output-side protection circuit. The protection circuit 23 is coupled to each of the internal circuit 24 and the output section matching circuit 4. It is to be noted that the protection circuit 23 has a configuration similar to the configuration of the protection circuit 22, and the description thereof will thus be omitted hereinafter.

The output section matching circuit 4 is mounted on a right side below the substrate 10. The output section matching circuit 4 outputs an RF signal to outside the RF power amplifier module 1.

The DC bias circuit 5 is mounted below the substrate 10. The DC bias circuit 5 is coupled to the semiconductor device 2. The DC bias circuit 5 is supplied with DC power from outside the RF power amplifier module 1.

Further, reference power GND is supplied to an unillustrated power supply wiring line provided in the substrate 10. The reference power GND is 0 V, for example.

### (2) Circuit Block Configuration of Protection Circuit 22 and Semiconductor Device 2

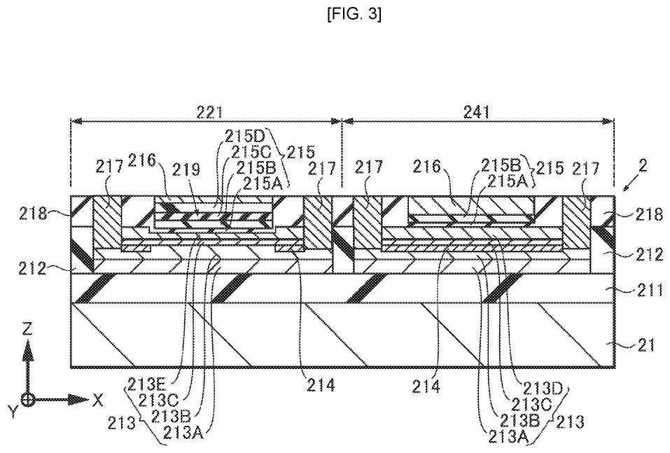

FIG. 2 illustrates a circuit block configuration of the protection circuit 22 as the input-side protection circuit of the semiconductor device 2 and the internal circuit 24.

The semiconductor device 2 includes an external terminal 201 as an input-side external terminal, and the internal circuit 24 coupled to the external terminal 201. The external terminal 201 and the internal circuit 24 are formed on a semiconductor substrate 21. The external terminal 201 is coupled to the input section matching circuit 3. Here, the internal circuit 24 is an RF power amplifier.

A coupling capacitor 202 is electrically coupled in series between the external terminal 201 and the internal circuit 24. Further, one end of a DC bias resistance 203 is coupled between the coupling capacitor 202 and the internal circuit 24, and another end of the DC bias resistance 203 is coupled to an external power supply terminal 208. The DC bias circuit 5 is coupled to the external power supply terminal 208 and, for example, negative DC bias power is supplied from the DC bias circuit 5. Moreover, one of electrodes of a decoupling capacitor 207 is coupled between the other end of the DC bias resistance 203 and the external power supply terminal 208. Another of the electrodes of the decoupling capacitor 207 is coupled to a reference power supply GND.

The semiconductor device 2 further includes the protection circuit 22 as the input-side protection circuit. In the first embodiment, the protection circuit 22 includes one MISFET 221. The MISFET 221 corresponds to a “first insulated gate field-effect transistor” according to the present technology.

In the MISFET 221, an electric charge accumulation section (see a reference numeral 219 in FIG. 3) configured to accumulate hot carriers is provided in a gate insulating film. The MISFET 221 is adjusted to a threshold voltage of a depletion type when no hot carriers are accumulated in the electric charge accumulation section. In contrast, when hot carriers are accumulated in the electric charge accumulation section, the MISFET 221 is adjusted to a threshold voltage of an enhancement type. The MISFET 221 is adjusted to the threshold voltage of the enhancement type when operated as the protection circuit 22.

A first main electrode (for example, a drain electrode) as one of main electrodes of the MISFET 221 is coupled between the external terminal 201 and the internal circuit 24 with the DC bias resistance 203 interposed therebetween. To be more specific, the first main electrode is coupled between the coupling capacitor 202 and the internal circuit 24. A second main electrode (for example, a source electrode) as another of the main electrodes and a gate electrode of the MISFET 221 are coupled to the reference power supply GND.

The protection circuit 22 further includes a resistance 222. The resistance 222 is electrically coupled in series between the second main electrode and the gate electrode of the MISFET 221. The resistance 222 corresponds to a “resistance” according to the present technology. The resistance 222 is set to a resistance value of, for example, 100 Ω or more and 10 MΩ or less. It is to be noted that as with the resistance 222, the DC bias resistance 203 is set to a resistance value of, for example, 10 Ω or more and 10 MΩ or less.

The protection circuit 22 is provided with a first external terminal 204, a second external terminal 205, and a third external terminal 206 for injecting hot carriers into the electric charge accumulation section of the MISFET 221. Here, the hot carriers are hot electrons. The first external terminal 204, the second external terminal 205, and the third external terminal 206 are provided on the semiconductor substrate 21.

The first external terminal 204 is coupled to the first main electrode of the MISFET 221. The first external terminal 204 corresponds to a “first external terminal” according to the present technology. The second external terminal 205 is coupled to the second main electrode. The second external terminal 205 corresponds to a “second external terminal” according to the present technology. The third external terminal 206 is coupled to the gate electrode. The third external terminal 206 corresponds to a “third external terminal” according to the present technology.

### (3) Vertical Cross-sectional Structure and Plan Structure of Protection Circuit 22 and Internal Circuit 24

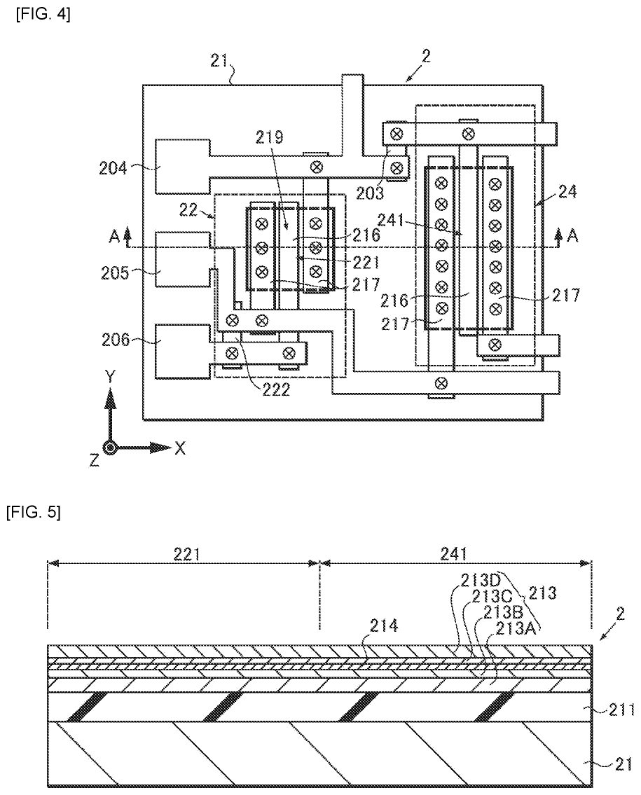

FIG. 3 illustrates a vertical cross-sectional structure of the protection circuit 22 and the internal circuit 24. Further, FIG. 4 illustrates a plan structure of the protection circuit 22 and the internal circuit 24. The internal circuit 24 includes a MISFET 241 constructing the internal circuit 24.

The MISFET 221 constructing the protection circuit 22 and the MISFET 241 constructing the internal circuit 24 are formed on the semiconductor substrate 21 with a buffer layer 211 interposed therebetween. For example, a Si substrate is used as the semiconductor substrate 21. In a case of a 6-inch Si wafer, the Si substrate is formed in a thickness of 600 μm or more and 700 μm or less. For example, the buffer layer 211 includes AlGaN. AlGaN is formed into a thickness of 0.3 μm or more and 1.0 μm or less by an epitaxial growth method, for example.

It is to be noted that a ceramic substrate such as a sapphire substrate may be used instead of the semiconductor substrate 21.

### (3-1) Configuration of MISFET 241

First, the MISFET 241 constructing the internal circuit 24 is provided on the buffer layer 211 in a region surrounded by an element separation section 212. The MISFET 241 includes a semiconductor layer 213, a two-dimensional electron gas (Two Dimensional Electron gas: hereinafter simply referred to as “2DEG”) 214, a gate insulating film 215, a gate electrode 216, and a pair of main electrodes 217. The MISFET 241 corresponds to a “second insulated gate field-effect transistor” according to the present technology.

At a location between the MISFETs 241 adjacent to each other, the element separation section 212 makes the semiconductor layer 213 amorphous and eliminates electrical conductivity of the 2DEG 214. The element separation section 212 is formed by an ion implantation method, for example. In the ion implantation method, for example, B ions are used as ions to be implanted. To be more specific, for example, B ions are implanted under a condition in which acceleration energy is 50 keV and an amount of dose is about 1×10¹⁵ ions/cm².

Here, the semiconductor layer 213 includes a GaN layer 213A, a GaN channel layer 213B, an AlN layer 213C, and an InAlN layer 213D.

The GaN layer 213A is stacked on the buffer layer 211. The GaN layer 213A is formed in a thickness of, for example, 0.8 μm or more and 1.5 μm or less.

The GaN channel layer 213B is stacked on the GaN layer 213A. The GaN channel layer 213B is formed in a thickness of, for example, 100 nm or more and 500 nm or less.

The AlN layer 213C is stacked on the GaN channel layer 213B. The AlN layer 213C is formed in a thickness of, for example, 0.5 nm or more and 1.5 nm or less.

The InAlN layer 213D is stacked on the AlN layer 213C. The InAlN layer 213D is formed in a thickness of, for example, 5 nm or more and 15 nm or less.

The 2DEG 214 is generated at the GaN channel layer 213B in the vicinity of an interface between the GaN channel layer 213B and the InAlN layer 213D to extend from one of the main electrodes 217 to another of the main electrodes 217. When no gate voltage is supplied to the gate electrode 216, the 2DEG 214 is formed at all times and therefore the MISFET 214 is in a conducting state. That is, the MISFET 214 is of the depletion type.

The MISFET 241 is configured with a high electron mobility transistor (High Electron Mobility Transistor; hereinafter simply referred to as “HEMT”) structure using a compound semiconductor material. In particular, the InAlN layer 213D is stacked and spontaneous polarization of the InAlN layer 213D is utilized for generation of the 2DEG 214, and this makes it possible to increase a carrier concentration of the 2DEG 214. Accordingly, employing the HEMT structure for the MISFET 241 makes it possible to enhance RF output power of the internal circuit 24, that is, the RF power amplifier.

The gate insulating film 215 is formed on the semiconductor layer 213. Here, the gate insulating film 215 includes a first oxide film 215A, and a second oxide film 215B stacked on the first oxide film 215A. The oxide films each include at least one or more selected from Al₂O₃, HfO₂, Ta₂O₅, ZrO₂, Y₂O₃, and SiO₂.

In the first embodiment, the first oxide film 215A includes Al₂O₃. The first oxide film 215A is formed in a thickness of, for example, 1 nm or more and 10 nm or less. Further, the second oxide film 215B includes HfO₂. The second oxide film 215B is formed in a thickness of, for example, 1 nm or more and 10 nm or less.

The gate electrode 216 is stacked on the gate insulating film 215. Here, the gate electrode 216 incudes a stacked film of, for example, Ni, and Au stacked on Ni. Ni is formed in a thickness of, for example, 30 nm or more and 50 nm or less. Au is formed in a thickness of, for example, 400 nm or more and 500 nm or less.

Further, a gate length dimension of the MISFET 241 is set to, for example, 0.1 μm or more and 0.3 μm or less. Here, the gate length dimension refers to a length of the gate electrode 216 in a direction (the arrow-X direction) coinciding with a direction in which the pair of main electrodes 217 are arranged.

The pair of main electrodes 217 are in contact with or on the 2DEG 214 and stacked on the GaN channel layer 213B. On of the pair of main electrodes 217 is used as a first main electrode, e.g., a drain electrode. The other of the main electrodes 217 is used as a second main electrode, e.g., a source electrode.

The main electrodes 217 are each formed by a thermal diffusion method with a stacked film including, for example, Ti, Al stacked on Ti, Ni stacked on Al, and Au stacked on Ni. The main electrodes 217 are ohmic (Ohmic) electrodes. Ti is formed in a thickness of, for example, 5 nm or more and 15 nm or less. Al is formed in a thickness of, for example, 50 nm or more and 150 nm or less. Ni is formed in a thickness of, for example, 15 nm or more and 25 nm or less. Au is formed in a thickness of, for example, 5 nm or more and 15 nm or less.

It is to be noted that an insulator 218 is provided between each of the gate insulating film 215 and the gate electrode 216 and the main electrode 217. The insulator 218 is provided also on the element separation section 212. The insulator 218 includes, for example, Al₂O₃.

### (3-2) Configuration of MISFET 221

In contrast, the MISFET 221 constructing the protection circuit 22 is provided on the buffer layer 211 in a region surrounded by the element separation section 212, as with the MISFET 241. The MISFET 221 includes the semiconductor layer 213, the 2DEG 214, the gate insulating film 215, the electric charge accumulation section 219, the gate electrode 216, and the pair of main electrodes 217. In the semiconductor layer 213, an InAlN layer 213E is provided instead of the InAlN layer 213D.

The electric charge accumulation section 219 is configured to accumulate hot carriers. In the MISFET 221, hot carriers are injected from the 2DEG 214 to the electric charge accumulation section 219 in the vicinity of the main electrode 217 serving as the drain electrode, and the injected hot carriers are accumulated in the electric charge accumulation section 219.

When no hot carriers are accumulated in the electric charge accumulation section 219, the 2DEG 214 is generated at the GaN channel layer 213B in the vicinity of an interface between the GaN channel layer 213B and the InAlN layer 213E to extend from one of the main electrodes 217 to the other of the main electrodes 217. That is, the MISFET 221 is produced as the depletion type.

In contrast, when the hot carriers are accumulated in the electric charge accumulation section 219, the 2DEG 214 below the electric charge accumulation section 219 disappears, and the threshold voltage shifts to a positive direction. That is, the MISFET 221 is adjusted to the threshold voltage of the enhancement type.

The InAlN layer 213E of the MISFET 221 is formed in a thickness smaller than the thickness of the InAlN layer 213D of the MISFET 241. For example, the thickness of the InAlN layer 213E of the MISFET 221 is formed to be 1 nm or more and 9 nm or less, thus being formed to be ⅕ times or more and ⅗ times or less the thickness of the InAlN layer 213D of the MISFET 241.

Forming the InAlN layer 213E to be small in thickness makes it possible to improve efficiency of injection of hot carriers into the electric charge accumulation section 219.

The gate insulating film 215 of the MISFET 221 includes the first oxide film 215A, the second oxide film 215B stacked on the first oxide film 215A, a nitride film 215C stacked on the second oxide film 215B, and a third oxide film 215D stacked on the nitride film 215C. The nitride film 215C includes SiN, for example. The nitride film 215C is formed in a thickness of, for example, 1 nm or more and 10 nm or less. The third oxide film 215D includes SiO₂, for example. The third oxide film 215D is formed in a thickness of, for example, 1 nm or more and 10 nm or less.

That is, for the gate insulating film 215, an ONO (Oxide-Nitride-Oxide) structure is employed in which an oxide film, a nitride film, and an oxide film are stacked one by one. Further, for the MISFET 221 including the semiconductor layer 213 and the gate electrode 216, a MONOS (Metal-Oxide-Nitride-Oxide-Semiconductor) structure is employed.

The electric charge accumulation section 219 includes the nitride film 215C having a hot carrier trap level. The electric charge accumulation section 219 may further include an interface between the nitride film 215C and the second oxide film 215B.

The gate length dimension of the MISFET 221 is set to, for example, 0.05 μm or more and 0.3 μm or less. Further, a gate width dimension of the MISFET 221 is set to, for example, 10 μm or more and 10000 μm or less. Here, the gate width dimension refers to a length of the gate electrode 216 in a gate width direction (the arrow-Y direction) orthogonal to a gate length direction.

### (4) Configuration of First External Terminal 204, Second External Terminal 205, and Third External Terminal 206

As illustrated in FIG. 4, the first external terminal 204, the second external terminal 205, and the third external terminal 206 include wiring lines in the same layer provided on the MISFET 241 and the MISFET 221. Here, the first external terminal 204, the second external terminal 205, and the third external terminal 206 are arranged in a line in the arrow-Y direction on the surface of the semiconductor substrate 21.

The first external terminal 204 and the like are formed in the same layer as that of the external terminal 201 that is illustrated in FIG. 2 and omitted here.

The first external terminal 204 is formed integrally with respective wiring lines, whose reference signs are omitted, that are coupled to the main electrode (the first main electrode) 217 of the MISFET 221 of the protection circuit 22, the DC bias resistance 203, and the external power supply terminal 208 (see FIG. 2).

The second external terminal 205 is formed integrally with respective wiring lines, whose reference signs are omitted, that are coupled to the resistance 222 and the main electrode (the second main electrode) 217 of the MISFET 221.

The third external terminal 206 is formed integrally with respective wiring lines, whose reference signs are omitted, that are coupled to the resistance 222 and the gate electrode 216 of the MISFET 221.

It is to be noted that as illustrated in FIG. 4, in a plan view, the MISFET 221 and the MISFET 241 are provided with their gate length directions coinciding with the arrow-X direction. It is to be noted that the MISFET 221 and the MISFET 241 may be provided without allowing their gate length directions to coincide with each other.

### (5) Configuration of Resistance 222 and DC Bias Resistance 203

As illustrated in FIG. 4, the resistance 222 and the DC bias resistance 203 are provided on the MISFET 221 and below the first external terminal 204. The resistance 222 and the DC bias resistance 203 each include a Ta cermet resistance, for example.

### [Method of Manufacturing Protection Circuit 22 and Semiconductor Device 2]

Next, a method of manufacturing the protection circuit 22 and the semiconductor device 2 will be described briefly.

FIGS. 5 to 12 illustrate cross sections in respective processes describing the method of manufacturing the protection circuit 22 and the semiconductor device 2.

First, the semiconductor substrate 21 is prepared (see FIG. 5). The buffer layer 211 is formed on the semiconductor substrate 21 (see FIG. 5).

As illustrated in FIG. 5, the semiconductor layer 213 is formed over an entire surface of the buffer layer 211. As described previously, the semiconductor layer 213 is formed by stacking the GaN layer 213A, the GaN channel layer 213B, the AlN layer 213C, and the InAlN layer 213D one by one. Upon forming the semiconductor layer 213, the 2DEG 214 is generated.

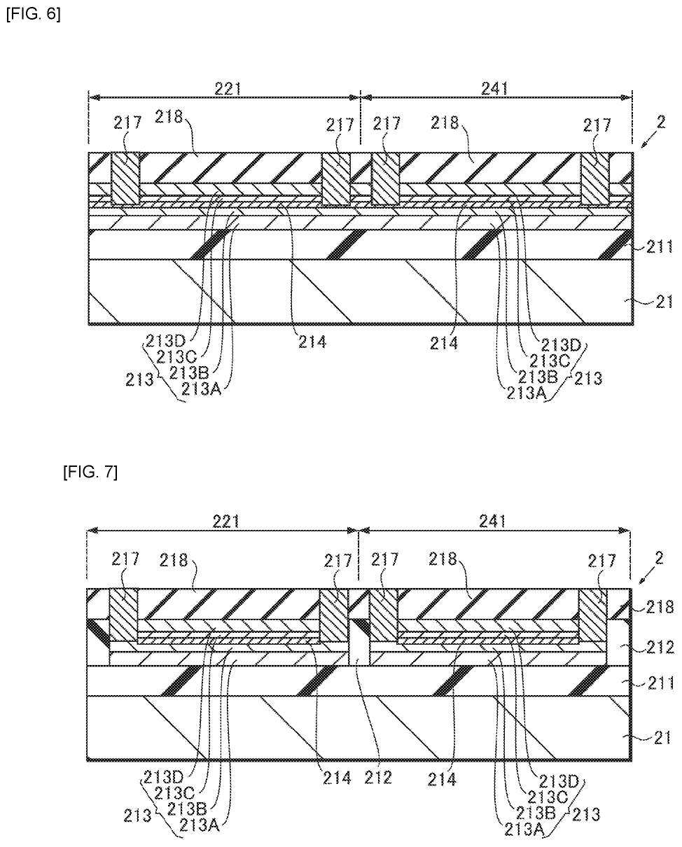

The insulator 218 is formed over an entire surface of the semiconductor layer 213 (see FIG. 6).

Next, as illustrated in FIG. 6, the pair of main electrodes 217 are formed in each of the formation regions of the MISFET 241 and the MISFET 221. The main electrodes 217 are each formed by forming, in the insulator 218, an opening at which the surface of the semiconductor layer 213 is exposed, and embedding an electrode material in the opening. The electrode material is deposited by, for example, a vacuum vapor deposition method or the like. Further, the deposited electrode material is subjected to heat treatment at a temperature of 500° C. or more and 700° C. or less by, for example, a thermal diffusion method. This provides the main electrodes 217 with an ohmic characteristic.

As illustrated in FIG. 7, the element separation section 212 is formed in the semiconductor layer 213 between the MISFET 221 and the MISFET 241 and between the MISFETs 241. As described previously, the element separation section 212 is formed by implanting ions into the semiconductor layer 213 by an ion implantation method.

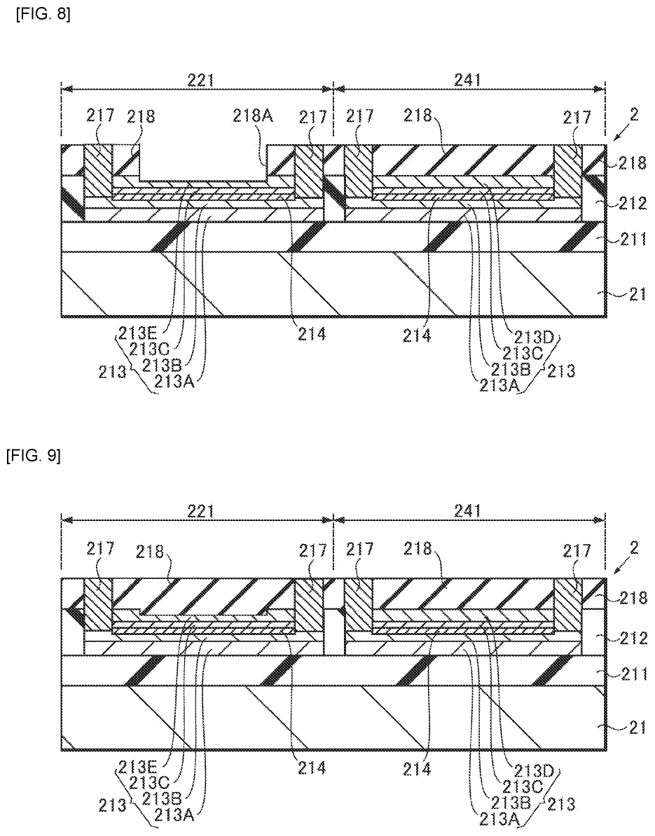

In a formation region of the gate insulating film 215 of the MISFET 221, an opening 218A is formed in the insulator 218 (see FIG. 8). The opening 218A is formed by, for example, a photolithography technique and an etching technique.

As illustrated in FIG. 8, subsequently to the formation of the opening 218A, a portion in the thickness direction of the InAlN layer 213D of the semiconductor layer 213 exposed from the opening 218A is etched. This forms the InAlN layer 213E that is smaller in thickness than the InAlN layer 213D.

As illustrated in FIG. 9, the opening 218A is embedded with the insulator 218.

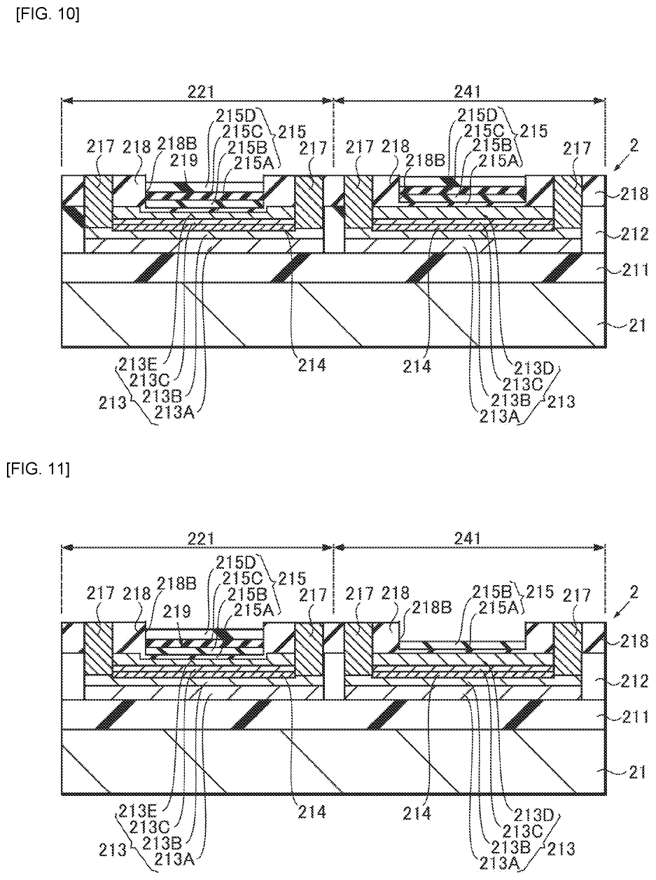

In each of the formation region of the gate insulating film 215 of the MISFET 221 and the formation region of the gate insulating film 215 of the MISFET 241, an opening 218B is formed in the insulator 218 (see FIG. 10). The opening 218B is formed by a photolithography technique and an etching technique.

As illustrated in FIG. 10, in the opening 218B, the gate insulating film 215 is formed on the InAlN layer 213E in the formation region of the MISFET 221. In the same manufacturing process, the gate insulating film 215 is further formed, in the opening 218B, on the InAlN layer 213D in the formation region of the MISFET 241.

The gate insulating film 215 is formed by stacking the first oxide film 215A, the second oxide film 215B, the nitride film 215C, and the third oxide film 215D one by one. The gate insulating film 215 is formed by an atomic layer deposition (Atomic Layer Deposition) method or the like, for example.

Here, in the MISFET 221, the gate insulating film 215 has the ONO structure, and accordingly, the electric charge accumulation section 219 is formed. Further, at this point in time, no hot carriers have been accumulated in the electric charge accumulation section 219, and the MISFET 221 is thus formed to have the threshold voltage of the depletion type.

As illustrated in FIG. 11, in the formation region of the MISFET 241, the third oxide film 215D and the nitride film 215C of the gate insulating film 215 are selectively removed. A photolithography technique and an etching technique are used for this removal. That is, in the MISFET 241, the electric charge accumulation section 219 is not formed. The MISFET 241 is formed to have the threshold voltage of the depletion type.

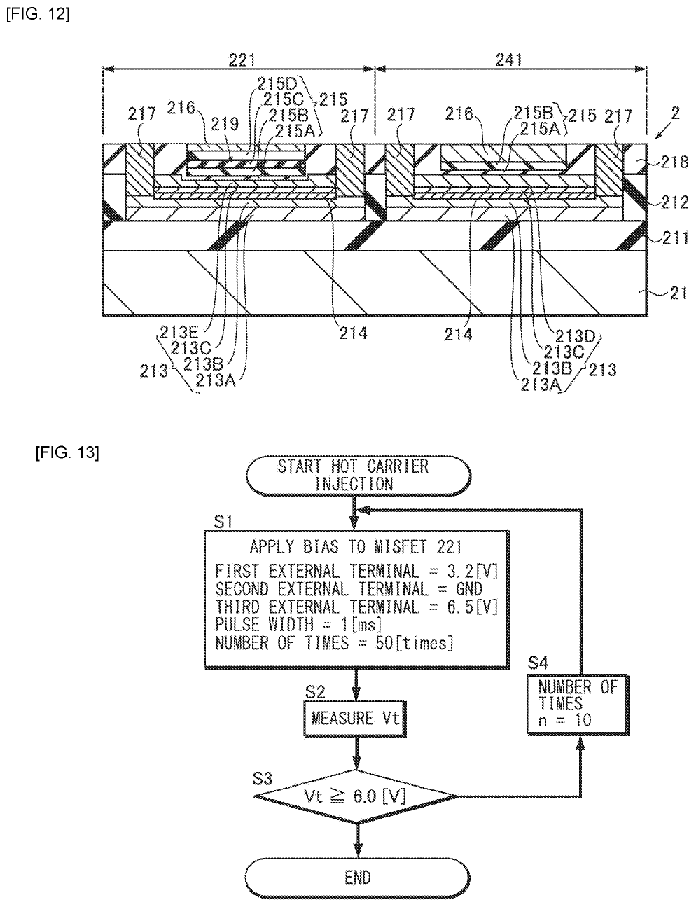

As illustrated in FIG. 12, in each of the formation region of the MISFET 221 and the formation region of the MISFET 241, the gate electrode 216 is formed on the gate insulating film 215. The MISFET 221 and the MISFET 241 are each completed when the gate electrode 216 is formed.

The resistance 222 and the DC bias resistance 203 are formed on the MISFET 221 and the MISFET 241, and the external terminal 201, the first external terminal 204 to the third external terminal 206, and the wiring lines are each formed in a further upper layer (see FIGS. 2 and 4). When the series of processes ends, the semiconductor device 2 including the protection circuit 22 and the internal circuit 24 is completed.

[Method of Electric Charge Accumulation into Electric Charge Accumulation Section 219]

In the protection circuit 22 illustrated in FIGS. 2 to 4, a method of electric charge accumulation into the electric charge accumulation section 219 of the MISFET 221 is as follows.

When the method of manufacturing the semiconductor device 2 illustrated in FIGS. 5 to 12 ends, hot carriers are injected into the electric charge accumulation section 219 of the MISFET 221 before mounting onto the RF power amplifier module 1. Here, a time before the mounting includes a time that is immediately after completion of a preprocessing process on the semiconductor device 2 and immediately after a characteristic inspection process on the semiconductor device 2.

It is to be noted that the injection of hot carriers may be performed after mounting of the semiconductor device 2 onto the RF power amplifier module 1.

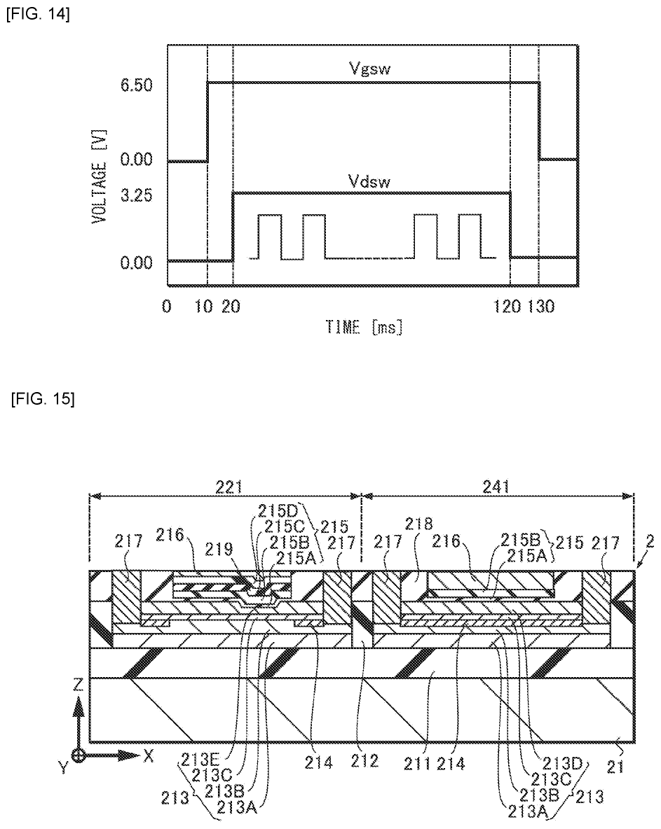

FIG. 13 illustrates a flowchart describing the electric charge accumulation method. Further, FIG. 14 illustrates a timing chart indicating a relationship between an injection voltage and an injection time for describing the electric charge accumulation method. Here, in FIG. 14, the horizontal axis represents time [ms], and the vertical axis represents voltage [V].

When the injection of hot carriers is started, the hot carriers start being injected into the electric charge accumulation section 219 of the MISFET 221 of the protection circuit 22 (step S1 in FIG. 13). In injecting the carriers, first power is supplied to the main electrode 217 of the MISFET 221 from the first external terminal 204 illustrated in FIGS. 2 and 4. This main electrode 217 is the first main electrode, and corresponds to the drain electrode. The first power is drain power. Further, second power is supplied to the main electrode 217 of the MISFET 221 from the second external terminal 205. This main electrode 217 is the second main electrode, and corresponds to the source electrode. The second power is source power. In addition, third power is supplied to the gate electrode 216 of the MISFET 221 from the third external terminal 206. The third power is gate power.

Here, assume that Vdsw represents a voltage between the drain electrode and the source electrode, BVpth represents a punchthrough voltage, Vt represents a threshold voltage, Vgsw represents a voltage between the gate electrode and the source electrode, BVg represents a gate breakdown voltage, and BVj represents a junction breakdown voltage. In this case, hot carriers are injected with conditions represented by Expressions <1> to <3> below satisfied.

$$\\ \begin{matrix}Vdsw < BVpth < Vt \leq Vgsw < BVg & < 1 >\end{matrix}$$

$$\\ \begin{matrix}Vdsw \approx Vgsw / 2 & < 2 >\end{matrix}$$

$$\\ \begin{matrix}BVpth \leq BVj & < 3 >\end{matrix}$$

Specifically, for example, Expression <1> above is calculated in accordance with Expression <4> below.

$$\\ \begin{matrix}3.25 [ V ] < 5.5 [ V ] < 6. [ V ] \leq 6.5 [ V ] < 15 [ V ] & < 4 >\end{matrix}$$

In step S1, on the basis of Expression <4> above, for example, 3.25 [V] is supplied to the first external terminal 204, 0 [V] is supplied to the second external terminal 205, and 6.5 [V] is supplied to the third external terminal 206 (see FIG. 14). The number of times the power is supplied is set to 50 times with a pulse width set to 1 [ms], for example. In this case, an injection time of hot carriers is set to, for example, 100 [ms], in consideration of repeatability.

Further, voltage conditions including the voltage Vdsw between the drain electrode and the source electrode are as follows, for example.
Vdsw: 1 [V] to 5 [V]
BVpth: 3.5 [V] to 7.5 [V]
Vt (after hot carrier injection): 4 [V] to 8 [V]
Vgsw: 4.5 [V] to 8.5 [V]
BVg: 13 [V] to 17 [V]
BVj: 8 [V] to 12 [V]

After step S1 ends, the threshold voltage Vt of the MISFET 221 is measured (step S2). On the basis of a measurement result, whether or not the threshold voltage Vt is greater than or equal to a predetermined value (here, 6.0 [V]) set in Expression <1> above is determined (step S3). When the threshold voltage Vt is greater than or equal to the predetermined value, the injection of hot carriers ends.

In contrast, when the threshold voltage Vt is less than the predetermined value in step S3, an additional number of times of supply of power is set (step S4). The additional number of times of supply of power is denoted as n, and n is set to 10 times, for example. In accordance with the additional number of times of supply of power, the flow returns to step S1 to continue the injection of hot carriers.

Thereafter, the injection of hot carriers ends when the threshold voltage Vt becomes greater than or equal to the predetermined value after going through step S2 and step S3. When the injection of hot carriers ends, the threshold voltage Vth of the MISTET 221 is formed into the enhancement type from the depletion type.

### [Circuit Operation of Protection Circuit 22]

In the MISFET 221 of the protection circuit 22, electric charge is accumulated in the electric charge accumulation section 219, and the threshold voltage Vt is set to be higher than a protection voltage Vesd (the punchthrough voltage VBpth). Accordingly, when at a voltage less than the protection voltage Vesd, a region between the pair of main electrodes 217 of the MISFET 221 exhibits a high resistance. That is, the protection circuit 22 exerts no influence on the operation of the internal circuit 24 at a signal voltage inputted to the external terminal 201.

As illustrated in FIG. 2, the DC bias circuit 5 that is externally attachable is coupled to the external power supply terminal 208 of the semiconductor device 2. At this time, if the DC bias circuit 5 is “positively” charged, a “positive” surge current Iesd flows from the DC bias circuit 5 to the semiconductor device 2 through the external power supply terminal 208. The surge current Iesd flows through the DC bias resistance 203 and the main electrode 217 used as the drain electrode of the MISFET 221. When a surge voltage is higher than or equal to the protection voltage Vesd, the MISFET 221 is low in resistance on a drain electrode side. Accordingly, the surge current lesd flows to the reference power supply GND through the drain electrode and the source electrode of the MISFET 221.

The region between the pair of main electrodes 217 of the MISFET 221 is adjusted to be at a constant punchthrough voltage BVpth by adjustment of the gate length dimension. Accordingly, the surge voltage is reduced to the protection voltage Vesd, and an ESD protection function is thus obtained.

In contrast, if the DC bias circuit 5 is “negatively” charged, conversely to a case where it is “positively” charged, the surge current lesd flows from the reference power supply GND through the MISFET 221 and the external power supply terminal 208.

The resistance 222 is provided between the gate electrode 216 of the MISFET 221 and the main electrode 217 used as the source electrode. Accordingly, a gate potential of the gate electrode 216 rises while a gate capacitance of the gate electrode 216 is charged through the resistance 222. At this time, because the region between the pair of electrodes 217 of the MISFET 221 is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent breakdown of the gate insulating film 215. Accordingly, it is possible to obtain the ESD protection function.

### [Workings and Effects]

The protection circuit 22 according to the first embodiment includes the MISFET 221, as illustrated in FIGS. 2 to 4. The MISFET 221 couples the main electrode (the first main electrode) 217 between the external terminal 201 and the internal circuit 24, and couples the main electrode (the second main electrode) 217 to the reference power supply GND. In addition, the electric charge accumulation section 219 configured to accumulate hot carriers is provided in the gate insulating film 215.

The MISFET 221 is formed as the depletion type and is able to be formed into the threshold voltage of the enhancement type by accumulation of hot carriers in the electric charge accumulation section 219. Accordingly, it is possible to construct the protection circuit 22 having superior ESD robustness or avalanche robustness, with use of the MISFET 221 that uses no pn junction and has a high process affinity.

In addition, the MISFET 211 uses no pn junction or no Schottky junction. Accordingly, it is possible to implement the protection circuit 22 that is free from a surge breakdown at a junction.

Further, as illustrated in FIGS. 2 and 4, the protection circuit 22 includes the resistance 222 that is electrically coupled in series between the gate electrode 216 of the MISFET 22 and the main electrode (the second main electrode) 217 used as the source electrode. This makes it unnecessary to separate the main electrodes 217 from each other when injecting hot carriers into the electric charge accumulation section 219.

In addition, it is possible to cause the electric charge accumulation section 219 to operate as the protection circuit 22 immediately after the injection of hot carriers thereinto.

Further in addition, even if a negative surge is inputted to the external power supply terminal 208, for example, the gate potential of the MISFET 221 does not immediately rise due to a CR delay operation, and in the meantime, a punchthrough occurs between the pair of main electrodes 217. Accordingly, it is possible to achieve protection against positive and negative surges with use of the MISFET 221 alone, without causing breakdown of the gate insulating film 215.

Further, as illustrated in FIGS. 2 and 4, the protection circuit 22 includes the first external terminal 204, the second external terminal 205, and the third external terminal 206. The first external terminal 204 is coupled between the external terminal 201 and the main electrode (the first main electrode) 217 of the MISFET 221, and the first power that generates hot carriers is supplied to the first external terminal 204. The second external terminal 205 is coupled to the main electrode (the second main electrode) 217 of the MISFET 221, and the second power that generates hot carriers is supplied to the second external terminal 205. The third external terminal 206 is coupled to the gate electrode 216 of the MISFET 221, and the third power that generates hot carriers is supplied to the third external terminal 206. The first external terminal 204, the second external terminal 205, and the third external terminal 206 are dedicated external terminals for injecting hot carriers into the MISFET 221.

Accordingly, it is possible to inject hot carriers into the electric charge accumulation section 219 on an as-needed basis immediately after production of the protection circuit 22 or thereafter to thereby start the protection function of the protection circuit 22.

Further, as illustrated in FIGS. 1 to 4, the semiconductor device 2 includes the external terminal 201, the internal circuit 24, and the protection circuit 22. The protection circuit 22 is provided on the semiconductor substrate 21 and includes the MISFET 221. The MISFET 221 couples the main electrode (the first main electrode) 217 between the external terminal 201 and the internal circuit 24, couples the main electrode (the second main electrode) 217 and the gate electrode 216 to the reference power supply GND, and provides the electric charge accumulation section 219 configured to accumulate hot carriers.

This makes it possible to obtain workings and effects similar to the workings and effects obtainable with the protection circuit 22 described above.

In addition, it is possible to construct the MISFET 221 of the protection circuit 22 easily with use of substantially the same structure or substantially the same manufacturing process as that used for the MISFET 241 constructing the internal circuit 24.

In addition, in the semiconductor device 2, the MISFET 221 of the protection circuit 22 further includes the resistance 222 that is electrically coupled in series between the gate electrode 216 and the main electrode (the second main electrode) 217.

Accordingly, the semiconductor device 2 makes it possible to obtain workings and effects similar to the workings and effects obtainable with the protection circuit 22 described above.

Further, as illustrated in FIGS. 2 and 4, the semiconductor device 2 includes the first external terminal 204, the second external terminal 205, and the third external terminal 206. Accordingly, the semiconductor device 2 makes it possible to obtain workings and effects similar to the workings and effects obtainable with the protection circuit 22 described above.

Furthermore, in the semiconductor device 2, as illustrated in FIG. 3, the electric charge accumulation section 219 of the MISFET 221 of the protection circuit 22 is configured with a structure in which an oxide film, a nitride film, and an oxide film are stacked one by one. To be more specific, the electric charge accumulation section 219 is configured with the ONO structure in which the first oxide film 215A, the second oxide film 215B, the nitride film 215C, and the third oxide film 215D are stacked one by one. The nitride film includes SiN. The oxide films each include at least one or more selected from Al₂O₃, HfO₂, Ta₂O₅, ZrO₂, Y₂O₃, and SiO₂. In the first embodiment, the electric charge accumulation section 219 includes Al₂O₃, HfO₂ stacked on Al₂O₃, SiN stacked on HfO₂, and SiO₂ stacked on SiN.

Accordingly, it is possible to construct the electric charge accumulation section 219 easily by employing the ONO structure for the gate insulating film 215.

Further, in the semiconductor device 2, as illustrated in FIG. 3, the MISFET 221 includes a compound semiconductor. To be more specific, the compound semiconductor includes GaN or GaAs. Further, the MISFET 221 includes InAlN.

Accordingly, it is possible to construct the protection circuit 22 with use of the MISFET 221 having the HEMT structure. In particular, it is possible to construct the protection circuit 22 easily with use of a structure substantially the same as the structure of the MISFET 241 constructing the internal circuit 24.

Further, in the semiconductor device 2, the MISFET 221 of the protection circuit 22 causes hot carriers to be accumulated in the electric charge accumulation section 219 and causes the threshold voltage to shift to the positive direction from the depletion type into the enhancement type.

Accordingly, the MISFET 221 of the protection circuit 22 is formed with use of substantially the same structure or substantially the same manufacturing process as that used for the MISFET 241 of the internal circuit 24. It is thus possible to construct the protection circuit 22 easily.

Further, in the semiconductor device 2, the gate length of the MISFET 221 of the protection circuit 22 illustrated in FIGS. 3 and 4 is formed to be 0.05 μm or more and 0.3 μm or less. In addition, the gate width of the MISFET 221 is formed to be 10 μm or more and 10000 μm or less. In addition, the resistance 222 of the protection circuit 22 is formed to be 100 Ω or more and 10 MΩ or less.

Accordingly, in the MISFET 221, it is possible to generate a punchthrough appropriately when a surge is inputted.

Further, in the semiconductor device 2, as illustrated in FIGS. 3 and 4, the internal circuit 24 includes the RF power amplifier including the MISFET 241 formed as the depletion type. Accordingly, it is possible to produce the protection circuit 22 easily with use of the structure and the manufacturing process of the MISFET 241 of the depletion type.

Moreover, in the semiconductor device 2, as illustrated in FIG. 3, the thickness of InAlN 213E of the MISFET 221 of the protection circuit 22 is smaller than the thickness of the InAlN 213D of the MISFET 241 of the internal circuit 24.

Accordingly, it is possible to improve efficiency of injection of hot carriers into the electric charge accumulation section 219 of the MISFET 221.

### 2. Second Embodiment

A description will be given of the protection circuit 22 and the semiconductor device 2 according to a second embodiment of the present disclosure. It is to be noted that in the second and subsequent embodiments, the same components or substantially the same components as those of the protection circuit 22 and the semiconductor device 2 according to the first embodiment are assigned the same reference numerals, and redundant descriptions will thus be omitted.

### [Configuration of Protection Circuit 22 and Semiconductor Device 2]

FIG. 15 illustrates a vertical cross-sectional structure of the protection circuit 22 and the internal circuit 24.

In the protection circuit 22 and the semiconductor device 2 according to the second embodiment, the MISFET 221 of the protection circuit 22 is provided with the InAlN layer 213E in a portion of the InAlN layer 213D of the semiconductor layer 213, the InAlN layer 213E being smaller in thickness than the InAlN layer 213D. To be more specific, the InAlN layer 213E is provided in the vicinity of the main electrode (the first main electrode) 217 used as the drain electrode in the gate length direction.

Hot carriers to be injected into the electric charge accumulation section 219 are generated in the vicinity of the drain electrode where electric field intensity becomes high.

Configurations except for the above are similar to the configurations of the protection circuit 22 and the semiconductor device 2 according to the first embodiment.

### [Workings and Effects]

The protection circuit 22 and the semiconductor device 2 according to the second embodiment make it possible to obtain workings and effects similar to the workings and effects obtainable with the protection circuit 22 and the semiconductor device 2 according to the first embodiment.

Moreover, as illustrated in FIG. 15, in the protection circuit 22 and the semiconductor device 2, the InAlN layer 213E that is small in thickness is provided in a portion of the InAlN layer 213D in the semiconductor layer 213 of the MISFET 221. Accordingly, it is possible to construct the MISFET 221 including the electric charge accumulation section 219 by means of minimum processing.

### 3. Third Embodiment

A description will be given of the protection circuit 22 and the semiconductor device 2 according to a third embodiment of the present disclosure. The third embodiment is a modification example of the protection circuit 22 and the internal circuit 24 according to the first embodiment.

### [Configuration of Protection Circuit 22 and Semiconductor Device 2]

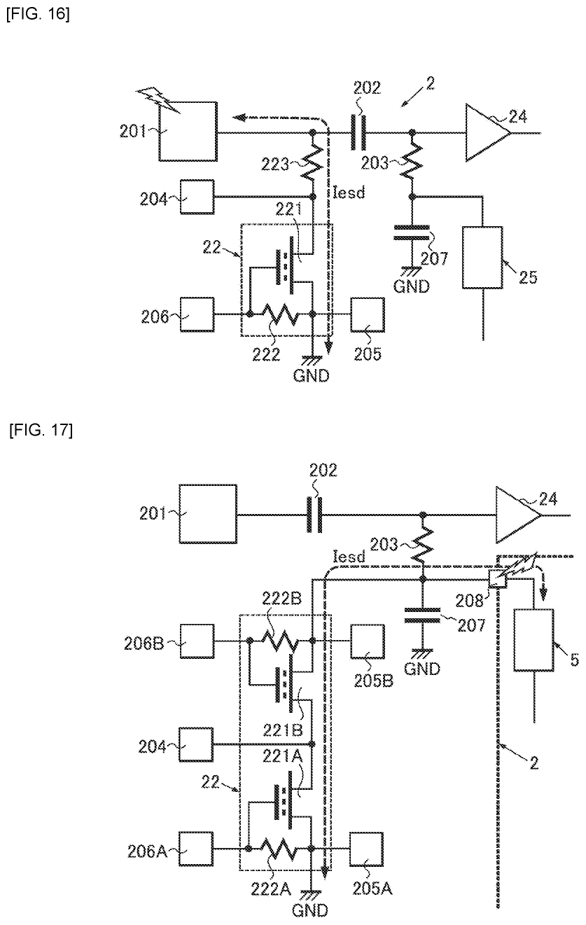

FIG. 16 illustrates a circuit block configuration of the protection circuit 22 as the input-side protection circuit of the semiconductor device 2 and the internal circuit 24.

In the protection circuit 22 and the semiconductor device 2 according to the third embodiment, the main electrode (the first main electrode) of the MISFET 221 is coupled between the external terminal 201 and the coupling capacitor 202 with a surge inductive resistance 223 interposed therebetween.

Further, the one end of the DC bias resistance 203 is coupled between the coupling capacitor 202 and the internal circuit 24, and the other end of the DC bias resistance 203 is coupled to the decoupling capacitor 207 and a DC bias circuit 25. The DC bias circuit 25 replaces the externally attachable DC bias circuit 5 and is contained in the semiconductor device 2.

Configurations except for the above are similar to the configurations of the protection circuit 22 and the semiconductor device 2 according to the first embodiment. [Circuit Operation of Protection Circuit 22]

In the MISFET 221 of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of the MISFET 221 exhibits a high resistance. That is, the protection circuit 22 exerts no influence on the operation of the internal circuit 24 at the signal voltage inputted to the external terminal 201.

As illustrated in FIG. 16, if a “positive” surge voltage is applied to the external terminal 201, the surge current lesd flows to the reference power supply GND side through the surge inductive resistance 223 and the pair of main electrodes of the MISFET 221 of the protection circuit 22.

The region between the pair of main electrodes of the MISFET 221 is at the constant punchthrough voltage BVpth by adjustment of the gate length dimension. Accordingly, the surge voltage is reduced to the protection voltage Vesd, and the ESD protection function is thus obtained.

Conversely, if a “negative” surge voltage is applied to the external terminal 201, the surge current Iesd flows from the reference power supply GND side to the external terminal 201 through the pair of main electrodes of the MISFET 221 and the surge inductive resistance 223.

The resistance 222 is provided between the gate electrode of the MISFET 221 and the main electrode used as the source electrode. Accordingly, the gate potential of the gate electrode rises while the gate capacitance of the gate electrode is charged through the resistance 222. At this time, because the region between the pair of electrodes of the MISFET 221 is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the third embodiment make it possible to obtain workings and effects similar to the workings and effects obtainable with the protection circuit 22 and the semiconductor device 2 according to the first embodiment.

Moreover, in the protection circuit 22 and the semiconductor device 2, protection against positive and negative surges is achievable with use of the MISFET 221 alone.

### 4. Fourth Embodiment

A description will be given of the protection circuit 22 and the semiconductor device 2 according to a fourth embodiment of the present disclosure. The fourth embodiment is a modification example of the protection circuit 22 and the semiconductor device 2 according to the first embodiment.

### [Configuration of Protection Circuit 22 and Semiconductor Device 2]

FIG. 17 illustrates a circuit block configuration of the protection circuit 22 as the input-side protection circuit of the semiconductor device 2 and the internal circuit 24.

In the protection circuit 22 and the semiconductor device 2 according to the fourth embodiment, the protection circuit 22 is coupled between the coupling capacitor 202 and the internal circuit 24 with the DC bias resistance 203 interposed therebetween.

The protection circuit 22 includes two MISFETs 221A and 221B that share the main electrode (here, the second main electrode) used as the drain electrode and are electrically coupled in series to each other. The second main electrode of the MISFET 221A and the MISFET 221B is coupled to the first external terminal 204.

The main electrode (here, the first main electrode) used as the source electrode of the MISFET 221B is coupled to the DC bias resistance 203.

A resistance 222A is electrically coupled in series between the first main electrode of the MISFET 221A and the gate electrode. The first main electrode of the MISFET 221A is coupled to a second external terminal 205A and the reference power supply GND. The gate electrode is coupled to a third external terminal 206A.

In contrast, a resistance 222B is electrically coupled in series between the first main electrode of the MISFET 221B and the gate electrode. The first main electrode of the MISFET 221B is coupled to a second external terminal 205B. The gate electrode is coupled to a third external terminal 206B. That is, the MISFET 221A and the MISFET 221B are disposed symmetrically with respect to the second main electrode.

The externally attachable DC bias circuit 5 is coupled to the external power supply terminal 208.

In the protection circuit 22, the injection of hot carriers into the electric charge accumulation section 219 is performed in the order of the MISFET 221A and the MISFET 221B or in the reverse order, or is performed on both of them simultaneously.

### [Circuit Operation of Protection Circuit 22]

In each of the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, a region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

In the protection circuit 22, the MISFET 221A and the MISFET 221B are stacked in two layers. The MISFET 221A and the MISFET 221B share the second main electrode. The first main electrode of the MISFET 221B is coupled to the external power supply terminal 208. The first main electrode of the MISFET 221A is coupled to the reference power supply GND. Thus, the protection voltage Vesd of the protection circuit 22 according to the fourth embodiment is approximately twice that of the protection circuit 22 according to the first embodiment.

Further, in the protection circuit 22 according to the first embodiment, a slight difference is observed between respective response characteristics to protection against the “positive” surge and the “negative” surge. In contrast, the protection circuit 22 according to the fourth embodiment exhibits substantially the same response characteristics to the protection because the MISFET 221A and the MISFET 221B are disposed symmetrically.

As illustrated in FIG. 17, the externally attachable DC bias circuit 5 is coupled to the external power supply terminal 208 of the semiconductor device 2. At this time, if the DC bias circuit 5 is “positively” charged, the “positive” surge current Iesd flows from the DC bias circuit 5 to the semiconductor device 2 through the external power supply terminal 208. The surge current lesd flows to the reference power supply GND through the MISFET 221B and the MISFET 221A of the protection circuit 22.

In contrast, if the DC bias circuit 5 is “negatively” charged, conversely to the case where it is “positively” charged, the surge current lesd flows from the reference power supply GND to the DC bias circuit 5 through the MISFET 221A, the MISFET 221B, and the external power supply terminal 208.

The resistance 222A is provided between the gate electrode of the MISFET 221A and the first main electrode used as the source electrode. The resistance 222B is provided between the gate electrode of the MISFET 221B and the main electrode used as the source electrode.

Accordingly, the surge current flowing from the source electrode side raises the gate potential of the gate electrode while allowing the gate capacitance of the gate electrode to be charged through the resistance 222A or the resistance 222B. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the fourth embodiment make it possible to obtain workings and effects similar to the workings and effects obtainable with the protection circuit 22 and the semiconductor device 2 according to the first embodiment.

Further, in the protection circuit 22, the MISFET 221A and the MISFET 221B are disposed symmetrically, which makes it possible to address positive and negative surge voltages. The protection voltage Vesd is approximately twice that of the protection circuit 22 according to the first embodiment: however, polarity variations of the punchthrough voltage BVpth are suppressed and transient response characteristics to the positive and negative surge voltages become the same.

Moreover, according to the protection circuit 22, because the protection voltage Vesd is approximately twice that in the case of a single device, a withstand voltage of an RF signal doubles, which makes it possible to achieve higher RF output power.

### 5. Fifth Embodiment

A description will be given of the protection circuit 22 and the semiconductor device 2 according to a fifth embodiment of the present disclosure. The fifth embodiment is a modification example in which the third embodiment and the fourth embodiment are combined.

### [Configuration of Protection Circuit 22 and Semiconductor Device 2]

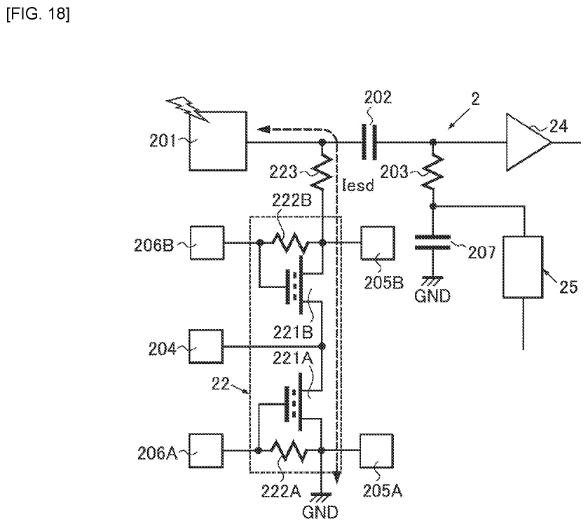

FIG. 18 illustrates a circuit block configuration of the protection circuit 22 as the input-side protection circuit of the semiconductor device 2 and the internal circuit 24. In the protection circuit 22 and the semiconductor device 2 according to the fifth embodiment, the protection circuit 22 is coupled between the external terminal 201 and the coupling capacitor 202 with the surge inductive resistance 223 interposed therebetween. The protection circuit 22 includes the two MISFETs 221A and 221B that are arranged symmetrically, as with the protection circuit 22 according to the fourth embodiment.

Further, the one end of the DC bias resistance 203 is coupled between the coupling capacitor 202 and the internal circuit 24, and the other end of the DC bias resistance 203 is coupled to the decoupling capacitor 207 and the DC bias circuit 25. The DC bias circuit 25 replaces the externally attachable DC bias circuit 5 and is contained in the semiconductor device 2.

Configurations except for the above are similar to the configurations of the protection circuit 22 and the semiconductor device 2 according to each of the third embodiment and the fourth embodiment.

### [Circuit Operation of Protection Circuit 22]

In the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

In the protection circuit 22, the MISFET 221A and the MISFET 221B are stacked in two layers. The MISFET 221A and the MISFET 221B share the second main electrode. The first main electrode of the MISFET 221B is coupled to the external terminal 201 through the surge inductive resistance 223. The first main electrode of the MISFET 221A is coupled to the reference power supply GND. Thus, the protection voltage Vesd of the protection circuit 22 according to the fifth embodiment is approximately twice that of the protection circuit 22 according to the first embodiment.

Further, in the protection circuit 22 according to the first embodiment, a slight difference is observed between the respective response characteristics to protection against the “positive” surge and the “negative” surge. In contrast, the protection circuit 22 according to the fifth embodiment exhibits substantially the same response characteristics to the protection because the MISFET 221A and the MISFET 221B are disposed symmetrically.

As illustrated in FIG. 18, if the “positive” surge voltage is applied to the external terminal 201, the surge current lesd flows to the reference power supply GND side through the surge inductive resistance 223, and the MISFET 221B and the MISFET 221A of the protection circuit 22.

The region between the pair of main electrodes of each of the MISFET 221A and the MISFET 221B is at the constant punchthrough voltage BVpth by adjustment of the gate length dimension. Accordingly, the surge voltage is reduced to the protection voltage Vesd, and the ESD protection function is thus obtained.

Conversely, if the “negative” surge voltage is applied to the external terminal 201, the surge current lesd flows from the reference power supply GND side to the external terminal 201 through the MISFET 221A, the MISFET 221B, and the surge inductive resistance 223.

The resistance 222A is provided between the gate electrode of the MISFET 221A and the main electrode used as the source electrode. The resistance 222B is provided between the gate electrode of the MISFET 221B and the main electrode used as the source electrode.

Accordingly, the surge current flowing from the source electrode side raises the gate potential of the gate electrode while allowing the gate capacitance of the gate electrode to be charged through the resistance 222A or the resistance 222B. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the fifth embodiment make it possible to obtain workings and effects as a resultant of combination of the workings and effects obtainable with the protection circuit 22 and the semiconductor device 2 according to the third embodiment and the workings and effects obtainable with the protection circuit 22 and the semiconductor device 2 according to the fourth embodiment.

### 6. Sixth Embodiment

A description will be given of the protection circuit 22 and the semiconductor device 2 according to a sixth embodiment of the present disclosure. The sixth embodiment is a modification example of the protection circuit 22 and the semiconductor device 2 according to the fourth embodiment.

### [Configuration of Protection Circuit 22 and Semiconductor Device 2]

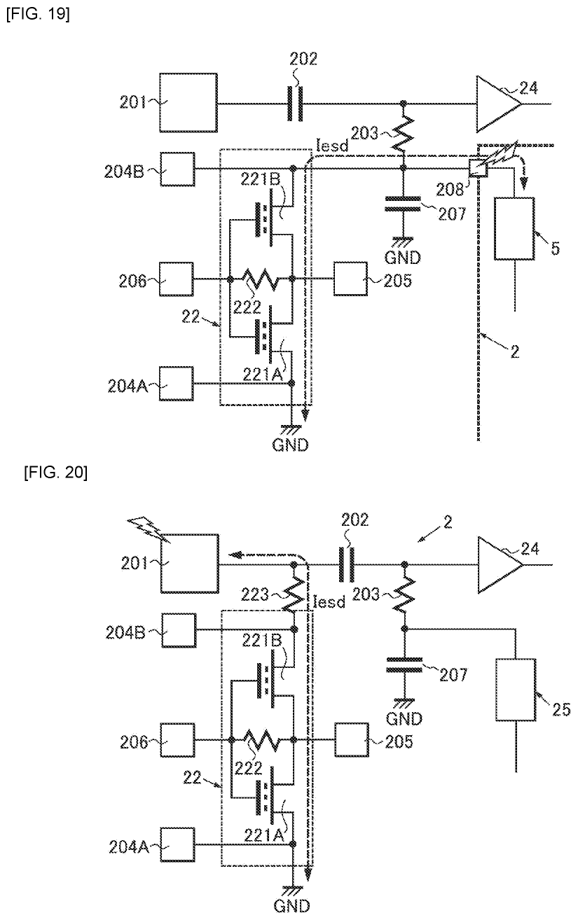

FIG. 19 illustrates a circuit block configuration of the protection circuit 22 as the input-side protection circuit of the semiconductor device 2 and the internal circuit 24.

In the protection circuit 22 and the semiconductor device 2 according to the sixth embodiment, the protection circuit 22 includes the two MISFETs 221A and 221B that share the main electrode (here, the second main electrode) used as the source electrode and are electrically coupled in series to each other. The second main electrode of the MISFET 221A and the MISFET 221B is coupled to the second external terminal 205.

The main electrode (here, the first main electrode) used as the drain electrode of the MISFET 221B is coupled to the DC bias resistance 203.

The resistance 222 for common use is electrically coupled in series between the second main electrode of the MISFET 221A and the gate electrode, and between the MISFET 221B and the second main electrode. The first main electrode of the MISFET 221A is coupled to a first external terminal 204A and the reference power supply GND. The gate electrode is coupled to the third external terminal 206 that is common to the gate electrode of the MISFET 221B.

In contrast, the first main electrode of the MISFET 221B is coupled to a first external terminal 204B.

The MISFET 221A and the MISFET 221B are disposed symmetrically with respect to the second main electrode.

The externally attachable DC bias circuit 5 is coupled to the external power supply terminal 208.

### [Circuit Operation of Protection Circuit 22]

In each of the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

In the protection circuit 22, the MISFET 221A and the MISFET 221B are stacked in two layers. The MISFET 221A and the MISFET 221B share the second main electrode. The first main electrode of the MISFET 221B is coupled to the external power supply terminal 208. The first main electrode of the MISFET 221A is coupled to the reference power supply GND. Thus, the protection voltage Vesd of the protection circuit 22 according to the sixth embodiment is approximately twice that of the protection circuit 22 according to the first embodiment.

Further, in the protection circuit 22 according to the first embodiment, a slight difference is observed between the respective response characteristics to protection against the “positive” surge and the “negative” surge. In contrast, the protection circuit 22 according to the sixth embodiment exhibits substantially the same response characteristics to the protection because the MISFET 221A and the MISFET 221B are disposed symmetrically.

As illustrated in FIG. 19, the externally attachable DC bias circuit 5 is coupled to the external power supply terminal 208 of the semiconductor device 2. At this time, if the DC bias circuit 5 is “positively” charged, the “positive” surge current lesd flows from the DC bias circuit 5 to the semiconductor device 2 through the external power supply terminal 208. The surge current Iesd flows to the reference power supply GND through the MISFET 221B and the MISFET 221A of the protection circuit 22.

In contrast, if the DC bias circuit 5 is “negatively” charged, conversely to the case where it is “positively” charged, the surge current Iesd flows from the reference power supply GND to the DC bias circuit 5 through the MISFET 221A, the MISFET 221B, and the external power supply terminal 208.

The resistance 222 is provided between the gate electrode of each of the MISFET 221A and the MISFET 221B and the second main electrode used as the source electrode.

Accordingly, the surge current flowing from the source electrode side raises the gate potential of the gate electrode while allowing the gate capacitance of the gate electrode to be charged through the resistance 222. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the sixth embodiment make it possible to obtain workings and effects similar to the workings and effects obtainable with the protection circuit 22 and the semiconductor device 2 according to the fourth embodiment.

### 7. Seventh Embodiment

A description will be given of the protection circuit 22 and the semiconductor device 2 according to a seventh embodiment of the present disclosure. The seventh embodiment is an example in which the protection circuit 22 and the semiconductor device 2 according to the fifth embodiment and the protection circuit 22 and the semiconductor device 2 according to the sixth embodiment are combined. [Configuration of Protection Circuit 22 and Semiconductor Device 2]

FIG. 20 illustrates a circuit block configuration of the protection circuit 22 as the input-side protection circuit of the semiconductor device 2 and the internal circuit 24.

In the protection circuit 22 and the semiconductor device 2 according to the seventh embodiment, the protection circuit 22 is coupled between the external terminal 201 and the coupling capacitor 202 with the surge inductive resistance 223 interposed therebetween. The protection circuit 22 includes the two MISFETs 221A and 221B that are arranged symmetrically, as with the protection circuit 22 according to the sixth embodiment.

Further, the one end of the DC bias resistance 203 is coupled between the coupling capacitor 202 and the internal circuit 24, and the other end of the DC bias resistance 203 is coupled to the decoupling capacitor 207 and the DC bias circuit 25. The DC bias circuit 25 replaces the externally attachable DC bias circuit 5 and is contained in the semiconductor device 2.

Configurations except for the above are similar to the configurations of the protection circuit 22 and the semiconductor device 2 according to each of the fifth embodiment and the sixth embodiment.

### [Circuit Operation of Protection Circuit 22]

In the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

In the protection circuit 22, the MISFET 221A and the MISFET 221B are stacked in two layers. The MISFET 221A and the MISFET 221B share the second main electrode. The first main electrode of the MISFET 221B is coupled to the external terminal 201 through the surge inductive resistance 223. The first main electrode of the MISFET 221A is coupled to the reference power supply GND. Thus, the protection voltage Vesd of the protection circuit 22 according to the seventh embodiment is approximately twice that of the protection circuit 22 according to the first embodiment.

Further, in the protection circuit 22 according to the first embodiment, a slight difference is observed between the respective response characteristics to protection against the “positive” surge and the “negative” surge. In contrast, the protection circuit 22 according to the seventh embodiment exhibits substantially the same response characteristics to the protection because the MISFET 221A and the MISFET 221B are disposed symmetrically.

As illustrated in FIG. 20, if the “positive” surge voltage is applied to the external terminal 201, the surge current lesd flows to the reference power supply GND side through the surge inductive resistance 223, and the MISFET 221B and the MISFET 221A of the protection circuit 22.

The region between the pair of main electrodes of each of the MISFET 221A and the MISFET 221B is at the constant punchthrough voltage BVpth by adjustment of the gate length dimension. Accordingly, the surge voltage is reduced to the protection voltage Vesd, and the ESD protection function is thus obtained.

Conversely, if the “negative” surge voltage is applied to the external terminal 201, the surge current lesd flows from the reference power supply GND side to the external terminal 201 through the MISFET 221A, the MISFET 221B, and the surge inductive resistance 223.

The resistance 222 is provided between the gate electrode of each of the MISFET 221A and the MISFET 221B and the main electrode used as the source electrode.

Accordingly, the surge current flowing from the source electrode side raises the gate potential of the gate electrode while allowing the gate capacitance of the gate electrode to be charged through the resistance 222. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the seventh embodiment make it possible to obtain workings and effects as a resultant of combination of the workings and effects obtainable with the protection circuit 22 and the semiconductor device 2 according to the fifth embodiment and the workings and effects obtainable with the protection circuit 22 and the semiconductor device 2 according to the sixth embodiment.

### 8. Eighth Embodiment

A description will be given of the protection circuit 22 and the semiconductor device 2 according to an eighth embodiment of the present disclosure. The eighth embodiment is a modification example of the protection circuit 22 and the semiconductor device 2 according to the sixth embodiment.

### [Configuration of Protection Circuit 22 and Semiconductor Device 2]

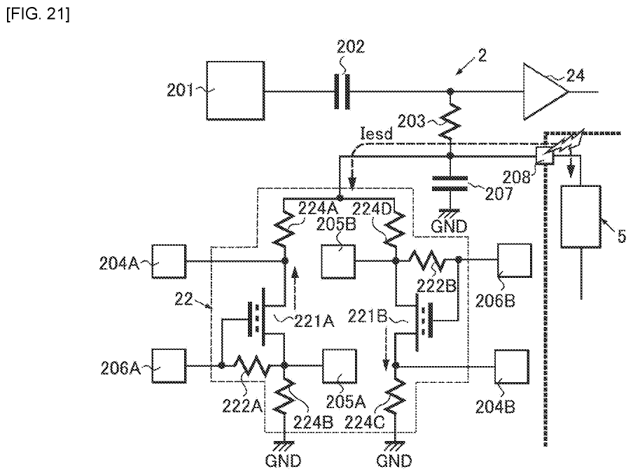

FIG. 21 illustrates a circuit block configuration of the protection circuit 22 as the input-side protection circuit of the semiconductor device 2 and the internal circuit 24.

In the protection circuit 22 and the semiconductor device 2 according to the eighth embodiment, the protection circuit 22 is coupled between the coupling capacitor 202 and the internal circuit 24 with the DC bias resistance 203 interposed therebetween.

The protection circuit 22 includes the two MISFETs 221A and 221B that are electrically coupled in parallel to each other.

The first main electrode used as a drain region of the MISFET 221A is coupled to the first external terminal 204A, and is coupled to the DC bias resistance 203 with a current mitigation resistance 224A interposed therebetween. The second main electrode used as the source electrode is coupled to the second external terminal 205A, and is coupled to the reference power supply GND with a current mitigation resistance 224B interposed therebetween. The gate electrode is coupled to the third external terminal 206A. The resistance 222A is electrically coupled in series between the second main electrode and the gate electrode.

The current mitigation resistance 224A and the current mitigation resistance 224B each mitigate the flow of current at the time of injection of hot carriers.

The first main electrode used as the drain region of the MISFET 221B is coupled to the first external terminal 204B, and is coupled to the reference power supply GND with a current mitigation resistance 224C interposed therebetween. The second main electrode used as the source electrode is coupled to the second external terminal 205B, and is coupled to the DC bias resistance 203 with a current mitigation resistance 224D interposed therebetween. The gate electrode is coupled to the third external terminal 206B. The resistance 222B is electrically coupled in series between the second main electrode and the gate electrode.

The current mitigation resistance 224C and the current mitigation resistance 224D each mitigate the flow of current at the time of injection of hot carriers.

The MISFET 221A and the MISFET 221B have a configuration in which the first main electrode and the second main electrode are opposite to each other in polarity.

The externally attachable DC bias circuit 5 is coupled to the external power supply terminal 208.

### [Circuit Operation of Protection Circuit 22]

In the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

Because the MISFET 221A and the MISFET 221B are disposed with their polarities being in opposite directions to each other, the protection voltage Vesd of the protection circuit 22 is equal to the protection voltage Vesd of the protection circuit 22 according to the first embodiment.

In the protection circuit 22 according to the first embodiment, a slight difference is observed between the respective response characteristics to protection against the “positive” surge and the “negative” surge. In contrast, the protection circuit 22 according to the eighth embodiment exhibits substantially the same response characteristics to the protection because the polarities of the MISFET 221A and the MISFET 221B are made to be in opposite left and right directions.

As illustrated in FIG. 21, the externally attachable DC bias circuit 5 is coupled to the external power supply terminal 208 of the semiconductor device 2. At this time, if the DC bias circuit 5 is “positively” charged, the “positive” surge current Iesd flows from the DC bias circuit 5 to the semiconductor device 2 through the external power supply terminal 208. The surge current lesd flows to the reference power supply GND through the MISFET 221A of the protection circuit 22.

In contrast, if the DC bias circuit 5 is “negatively” charged, conversely to the case where it is “positively” charged, the surge current lesd flows from the reference power supply GND to the DC bias circuit 5 through the MISFET 221B and the external power supply terminal 208.

The resistance 222A is provided between the gate electrode of the MISFET 221A and the second main electrode. The resistance 222B is provided between the gate electrode of the MISFET 221B and the second main electrode.

Accordingly, the surge current flowing from the source electrode side raises the gate potential of the gate electrode while allowing the gate capacitance of the gate electrode to be charged through the resistance 222A or the resistance 222B. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the eighth embodiment make it possible to obtain workings and effects similar to the workings and effects obtainable with the protection circuit 22 and the semiconductor device 2 according to the first embodiment.

Moreover, because the protection circuit 22 includes the MISFET 221A and the MISFET 221B whose polarities are set to opposite directions to each other, it is possible to effectively suppress polarity variations of the surge. Further, it is possible to make the transient response characteristics to the positive and negative surges equal.

### 9. Ninth Embodiment

A description will be given of the protection circuit 22 and the semiconductor device 2 according to a ninth embodiment of the present disclosure. The ninth embodiment is an example in which the protection circuit 22 and the semiconductor device 2 according to the seventh embodiment and the protection circuit 22 and the semiconductor device 2 according to the eighth embodiment are combined.

### [Configuration of Protection Circuit 22 and Semiconductor Device 2]

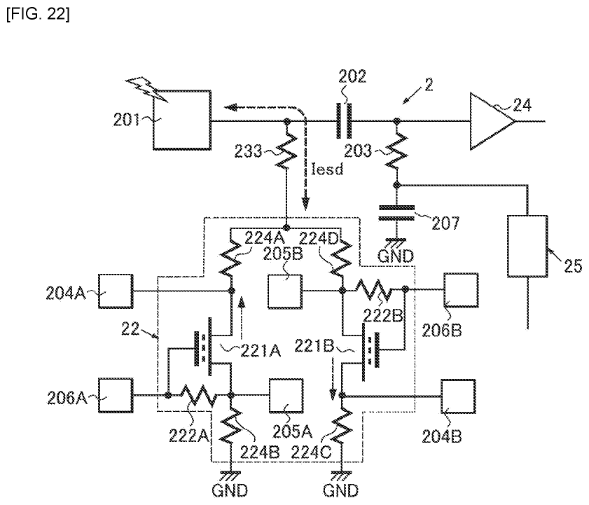

FIG. 22 illustrates a circuit block configuration of the protection circuit 22 as the input-side protection circuit of the semiconductor device 2 and the internal circuit 24. In the protection circuit 22 and the semiconductor device 2 according to the ninth embodiment, the protection circuit 22 is coupled between the external terminal 201 and the coupling capacitor 202 with the surge inductive resistance 223 interposed therebetween.

The protection circuit 22 includes the two MISFETs 221A and 221B that are electrically coupled in parallel to each other, as with the protection circuit 22 according to the eighth embodiment.

A configuration and a circuit operation except for the above are substantially the same as the configuration and the circuit operation of the protection circuit 22 according to the seventh embodiment and those of the protection circuit 22 according to the eighth embodiment, and descriptions thereof will thus be omitted here.

### [Workings and Effects]

The protection circuit 22 and the semiconductor device 2 according to the ninth embodiment make it possible to obtain workings and effects as a resultant of combination of the workings and effects obtainable with the protection circuit 22 and the semiconductor device 2 according to the seventh embodiment and the workings and effects obtainable with the protection circuit 22 and the semiconductor device 2 according to the eighth embodiment.

### 10. Tenth Embodiment

A description will be given of the protection circuit 22 and the semiconductor device 2 according to a tenth embodiment of the present disclosure. The tenth embodiment is a modification example of the protection circuit 22 and the semiconductor device 2 according to the eighth embodiment.

### [Configuration of Protection Circuit 22 and Semiconductor Device 2]

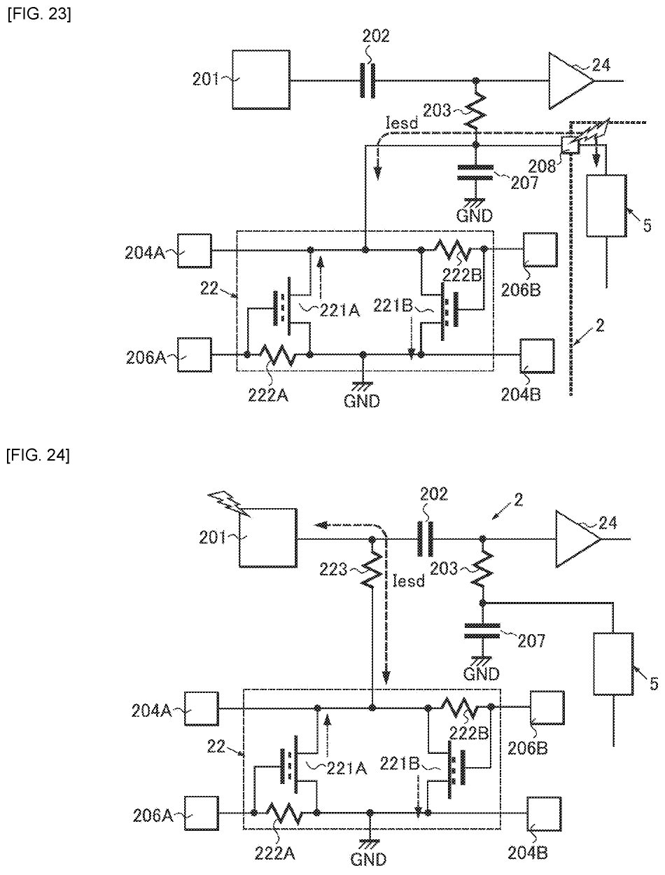

FIG. 23 illustrates a circuit block configuration of the protection circuit 22 as the input-side protection circuit of the semiconductor device 2 and the internal circuit 24.

In the protection circuit 22 and the semiconductor device 2 according to the tenth embodiment, the protection circuit 22 is coupled between the coupling capacitor 202 and the internal circuit 24 with the DC bias resistance 203 interposed therebetween.

The protection circuit 22 includes the two MISFETs 221A and 221B that are electrically coupled in parallel to each other.

The first main electrode used as the drain region of the MISFET 221A is coupled to the first external terminal 204A, and is coupled to the DC bias resistance 203. The second main electrode used as the source electrode is coupled to the first external terminal 204B, and is coupled to the reference power supply GND. The gate electrode is coupled to the third external terminal 206A. The resistance 222A is electrically coupled in series between the second main electrode and the gate electrode.

The first main electrode used as the drain region of the MISFET 221B is coupled to the first external terminal 204B, and is coupled to the reference power supply GND. The first external terminal 204B is also coupled to the second main electrode of the MISFET 221A. The second main electrode used as the source electrode is coupled to the first external terminal 204A, and is coupled to the DC bias resistance 203. The first external terminal 204A is also coupled to the first main electrode of the MISFET 221A. The gate electrode is coupled to the third external terminal 206B. The resistance 222B is electrically coupled in series between the second main electrode and the gate electrode.

The MISFET 221A and the MISFET 221B have a configuration in which the first main electrode and the second main electrode are opposite to each other in polarity.

The externally attachable DC bias circuit 5 is coupled to the external power supply terminal 208.

### [Circuit Operation of Protection Circuit 22]

In the MISFET 221A and the MISFET 221B of the protection circuit 22, electric charge is accumulated in the electric charge accumulation section 219, and the threshold voltage Vt is set to be higher than the protection voltage Vesd (the punchthrough voltage VBpth). Accordingly, when at a voltage less than the protection voltage Vesd, the region between the pair of main electrodes of each of the MISFET 221A and the MISFET 221B exhibits a high resistance. That is, the protection circuit 22 exerts no influence on the operation of the internal circuit 24 at the signal voltage inputted to the external terminal 201.

Because the MISFET 221A and the MISFET 221B are disposed with their polarities being in opposite directions to each other, the protection voltage Vesd of the protection circuit 22 is equal to the protection voltage Vesd of the protection circuit 22 according to the first embodiment.

In the protection circuit 22 according to the first embodiment, a slight difference is observed between the respective response characteristics to protection against the “positive” surge and the “negative” surge. In contrast, the protection circuit 22 according to the tenth embodiment exhibits substantially the same response characteristics to the protection because the polarities of the MISFET 221A and the MISFET 221B are made to be in opposite left and right directions.

As illustrated in FIG. 23, the externally attachable DC bias circuit 5 is coupled to the external power supply terminal 208 of the semiconductor device 2. At this time, if the DC bias circuit 5 is “positively” charged, the “positive” surge current Iesd flows from the DC bias circuit 5 to the semiconductor device 2 through the external power supply terminal 208. The surge current lesd flows to the reference power supply GND through the MISFET 221A of the protection circuit 22.

In contrast, if the DC bias circuit 5 is “negatively” charged, conversely to the case where it is “positively” charged, the surge current lesd flows from the reference power supply GND to the DC bias circuit 5 through the MISFET 221B and the external power supply terminal 208.

The resistance 222A is provided between the gate electrode of the MISFET 221A and the second main electrode. The resistance 222B is provided between the gate electrode of the MISFET 221B and the second main electrode.

Accordingly, the surge current flowing from the source electrode side raises the gate potential of the gate electrode while allowing the gate capacitance of the gate electrode to be charged through the resistance 222A or the resistance 222B. At this time, because the region between the pair of main electrodes of each of the MISFET 221A and the MISFET 221B is at the constant punchthrough voltage BVpth by adjustment of the gate length dimension, the surge voltage is reduced to the protection voltage Vesd. That is, the gate potential does not rise to be greater than or equal to the protection voltage Vesd, and it is thus possible to effectively suppress or prevent the breakdown of the gate insulating film. Accordingly, it is possible to obtain the ESD protection function.

### [Workings and Effects]

The protection circuit 22 and the semiconductor device 2 according to the tenth embodiment make it possible to obtain workings and effects similar to the workings and effects obtainable with the protection circuit 22 and the semiconductor device 2 according to the eighth embodiment.

Moreover, in the protection circuit 22, the first external terminal 204A also serves as an external terminal that couples the first main electrode of the MISFET 221A and the second main electrode of the MISFET 221B to each other. Similarly, the second external terminal 204B also serves as an external terminal that couples the second main electrode of the MISFET 221A and the first main electrode of the MISFET 221B to each other. Accordingly, it is possible to reduce the number of external terminals for injecting hot carriers.

### 11. Eleventh Embodiment

A description will be given of the protection circuit 22 and the semiconductor device 2 according to an eleventh embodiment of the present disclosure. The eleventh embodiment is an example in which the protection circuit 22 and the semiconductor device 2 according to the ninth embodiment and the protection circuit 22 and the semiconductor device 2 according to the tenth embodiment are combined.

[Configuration of Protection Circuit 22 and Semiconductor Device 2]

FIG. 24 illustrates a circuit block configuration of the protection circuit 22 as the input-side protection circuit of the semiconductor device 2 and the internal circuit 24.

In the protection circuit 22 and the semiconductor device 2 according to the eleventh embodiment, the protection circuit 22 is coupled between the external terminal 201 and the coupling capacitor 202 with the surge inductive resistance 223 interposed therebetween.

The protection circuit 22 includes the two MISFETs 221A and 221B that are electrically coupled in parallel to each other, as with the protection circuit 22 according to the tenth embodiment.

A configuration and a circuit operation except for the above are substantially the same as the configuration and the circuit operation of the protection circuit 22 according to the ninth embodiment and those of the protection circuit 22 according to the tenth embodiment, and descriptions thereof will thus be omitted here.

### [Workings and Effects]

The protection circuit 22 and the semiconductor device 2 according to the eleventh embodiment make it possible to obtain workings and effects as a resultant of combination of the workings and effects obtainable with the protection circuit 22 and the semiconductor device 2 according to the ninth embodiment and the workings and effects obtainable with the protection circuit 22 and the semiconductor device 2 according to the tenth embodiment.

### 12. Twelfth Embodiment

A description will be given of the protection circuit 22 and the semiconductor device 2 according to a twelfth embodiment of the present disclosure. The twelfth embodiment is a modification example of the protection circuit 22 and the semiconductor device 2 according to the first embodiment.

### [Configuration of Protection Circuit 22 and Semiconductor Device 2]

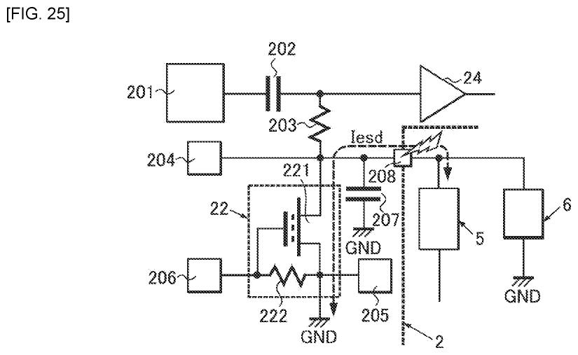

FIG. 25 illustrates a circuit block configuration of the protection circuit 22 as the input-side protection circuit of the semiconductor device 2 and the internal circuit 24.

In the protection circuit 22 and the semiconductor device 2 according to the twelfth embodiment, an externally attachable protection element 6 is coupled to the external power supply terminal 208, being electrically in parallel to the DC bias circuit 5. The externally attachable protection element 6 has further higher ESD protection robustness relative to the ESD protection robustness of the protection circuit 22. For example, a GGnMOS-Tr (Gate Grounded n-type MOSFET), pn diode, or the like is practically usable as the externally attachable protection element 6.

A configuration and a circuit operation except for the above are substantially the same as the configuration and the circuit operation of the protection circuit 22 according to the first embodiment, and descriptions thereof will thus be omitted here.

### [Workings and Effects]

The protection circuit 22 and the semiconductor device 2 according to the twelfth embodiment make it possible to obtain workings and effects similar to the workings and effects obtainable with the protection circuit 22 and the semiconductor device 2 according to the first embodiment.

Moreover, owing to the provision of the externally attachable protection element 6, it is possible to further improve the ESD robustness of the semiconductor device 2.

### 13. Other Embodiments

The present technology is not limited to the embodiments described above, and various modifications may be made without departing from the gist of the present technology.

For example, the protection circuits and the semiconductor devices according to any two or more of the first to twelfth embodiments described above may be combined.

Further, although the description has been given of the input-side protection circuit by way of example, the present technology may be applied to the output-side protection circuit.

Further, the present technology may be applied not only to the insulated gate field-effect transistor that includes the compound semiconductor material but also to a protection circuit and a semiconductor device each including an insulated gate field-effect transistor that includes a Si semiconductor material.

The protection circuit according to the first embodiment of the present disclosure includes the MISFET. The MISFET couples the first main electrode between the external terminal and the internal circuit, and couples the second main electrode to the reference power supply. In addition, the electric charge accumulation section configured to accumulate hot carriers is provided in the gate insulating film.

The MISFET is formed as the depletion type and is able to be formed into the threshold voltage of the enhancement type by accumulating hot carriers in the electric charge accumulation section. Accordingly, it is possible to construct the protection circuit having superior ESD robustness or avalanche robustness, with use of the MISFET that uses no pn junction and has a high process affinity.

Further, the semiconductor device according to the second embodiment of the present disclosure includes the external terminal, the internal circuit, and the protection circuit. The protection circuit is provided on the semiconductor substrate and includes the MISFET. The MISFET couples the first main electrode between the external terminal and the internal circuit, couples the second main electrode and the gate electrode to the reference power supply, and provides the electric charge accumulation section configured to accumulate hot carriers. Accordingly, it is possible to obtain workings and effects similar to the workings and effects obtainable with the protection circuit described above.

### <Configuration of Present Technology>

The present technology includes the following configurations. The present technology having the following configurations makes it possible to construct the protection circuit and the semiconductor device that are superior in ESD robustness or avalanche robustness, with use of the MISFET having a high process affinity.
(1)
A protection circuit including
a first insulated gate field-effect transistor in which: a first main electrode is coupled between an external terminal and an internal circuit: a second main electrode and a gate electrode are coupled to a reference power supply: and an electric charge accumulation section configured to accumulate hot carriers is provided in a gate insulating film.
(2)
The protection circuit according to (1) described above, further including a resistance that is electrically coupled in series between the gate electrode and the second main electrode.
(3)
The protection circuit according to (1) or (2) described above, further including:
a first external terminal coupled between the external terminal and the first main electrode and receiving supply of first power that generates hot carriers;
a second external terminal coupled to the second main electrode and receiving supply of second power that generates hot carriers; and
a third external terminal coupled to the gate electrode and receiving supply of third power that generates hot carriers.
(4)
A semiconductor device including
an external terminal provided on a substrate,
an internal circuit provided on the substrate and coupled to the external terminal, and
a protection circuit provided on the substrate and including a first insulated gate field-effect transistor in which: a first main electrode is coupled between the external terminal and the internal circuit; a second main electrode and a gate electrode are coupled to a reference power supply; and an electric charge accumulation section configured to accumulate hot carriers is provided in a gate insulating film.
(5)
The semiconductor device according to (4) described above, in which the protection circuit further includes a resistance that is electrically coupled in series between the gate electrode and the second main electrode.
(6)
The semiconductor device according to (4) or (5) described above, further including:
a first external terminal coupled between the external terminal and the first main electrode and receiving supply of first power that generates hot carriers;
a second external terminal coupled to the second main electrode and receiving supply of second power that generates hot carriers; and
a third external terminal coupled to the gate electrode and receiving supply of third power that generates hot carriers.
(7)
The semiconductor device according to any one of (4) to (6) described above, in which the electric charge accumulation section is configured with a structure in which an oxide film, a nitride film, and an oxide film are stacked one by one.
(8)
The semiconductor device according to (7) described above, in which
the nitride film includes SiN, and
the oxide film includes at least one or more selected from Al₂O₃, HfO₂, Ta₂O₅, ZrO₂, Y₂O₃, and SiO₂.
(9)
The semiconductor device according to (7) described above, in which the electric charge accumulation section includes Al₂O₃, HfO₂ stacked on the Al₂O₃, SiN stacked on the HfO₂, and SiO₂ stacked on the SiN.
(10)
The semiconductor device according to any one of (4) to (9) described above, in which the first insulated gate field-effect transistor includes a compound semiconductor.
(11)
The semiconductor device according to (10) described above, in which the compound semiconductor includes GaN or GaAs.
(12)
The semiconductor device according to (11) described above, in which the first insulated gate field-effect transistor includes InAlN.
(13)
The semiconductor device according to any one of (4) to (12) described above, in which the first insulated gate field-effect transistor causes hot carriers to be accumulated in the electric charge accumulation section and causes a threshold voltage to shift to a positive direction from a depletion type into an enhancement type. (14)
The semiconductor device according to any one of (4) to (13) described above, in which
a gate length of the first insulated gate field-effect transistor in a direction coinciding with a direction in which the first main electrode and the second main electrode are disposed is formed to be 0.05 μm or more and 0.3 μm or less, and
a gate width in a direction intersecting the direction of the gate length is formed to be 10 μm or more and 10000 μm or less.
(15)
The semiconductor device according to (5) described above, in which the resistance is formed to be 100 Ω or more and 10 MΩ or less.
(16)
The semiconductor device according to any one of (4) to (15) described above, further including a power amplifier including a second insulated gate field-effect transistor formed as a depletion type.
(17)
The semiconductor device according to (16) described above, in which
the first insulated gate field-effect transistor and the second insulated gate field-effect transistor each include InAlN, and
a thickness of at least a portion of InAlN in the first insulated gate field-effect transistor is smaller than a thickness of InAlN in the second insulated gate field-effect transistor.
(18)
The semiconductor device according to any one of (4) to (17) described above, further including an inductive resistance that is electrically coupled in series between the external terminal and the first main electrode.
(19)
The semiconductor device according to any one of (4) to (18) described above, further including a coupling capacitor that is electrically coupled in series between the external terminal and the internal circuit.
(20)
The semiconductor device according to any one of (4) to (19) described above, in which a plurality of the first insulated gate field-effect transistors is provided symmetrically.

The present application claims the benefit of Japanese Priority Patent Application JP2021-114604 filed with the Japan Patent Office on Jul. 9, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A protection circuit comprising
a first insulated gate field-effect transistor in which: a first main electrode is coupled between an external terminal and an internal circuit; a second main electrode and a gate electrode are coupled to a reference power supply; and an electric charge accumulation section configured to accumulate hot carriers is provided in a gate insulating film.

2. The protection circuit according to claim 1, further comprising a resistance that is electrically coupled in series between the gate electrode and the second main electrode.

3. The protection circuit according to claim 2, further comprising:
a first external terminal coupled between the external terminal and the first main electrode and receiving supply of first power that generates hot carriers;
a second external terminal coupled to the second main electrode and receiving supply of second power that generates hot carriers; and
a third external terminal coupled to the gate electrode and receiving supply of third power that generates hot carriers.

4. A semiconductor device comprising
an external terminal provided on a substrate,
an internal circuit provided on the substrate and coupled to the external terminal, and
a protection circuit provided on the substrate and including a first insulated gate field-effect transistor in which: a first main electrode is coupled between the external terminal and the internal circuit; a second main electrode and a gate electrode are coupled to a reference power supply; and an electric charge accumulation section configured to accumulate hot carriers is provided in a gate insulating film.

5. The semiconductor device according to claim 4, wherein the protection circuit further includes a resistance that is electrically coupled in series between the gate electrode and the second main electrode.

6. The semiconductor device according to claim 5, further comprising:
a first external terminal coupled between the external terminal and the first main electrode and receiving supply of first power that generates hot carriers;
a second external terminal coupled to the second main electrode and receiving supply of second power that generates hot carriers; and
a third external terminal coupled to the gate electrode and receiving supply of third power that generates hot carriers.

7. The semiconductor device according to claim 4, wherein the electric charge accumulation section is configured with a structure in which an oxide film, a nitride film, and an oxide film are stacked one by one.

8. The semiconductor device according to claim 7, wherein
the nitride film includes SiN, and
the oxide film includes at least one or more selected from Al₂O₃, HfO₂, Ta₂O₅, ZrO₂, Y₂O₃, and SiO₂.

9. The semiconductor device according to claim 7, wherein the electric charge accumulation section includes Al₂O₃, HfO₂ stacked on the Al₂O₃, SiN stacked on the HfO₂, and SiO₂ stacked on the SiN.

10. The semiconductor device according to claim 4, wherein the first insulated gate field-effect transistor includes a compound semiconductor.

11. The semiconductor device according to claim 10, wherein the compound semiconductor includes GaN or GaAs.

12. The semiconductor device according to claim 11, wherein the first insulated gate field-effect transistor includes InAlN.

13. The semiconductor device according to claim 4, wherein the first insulated gate field-effect transistor causes hot carriers to be accumulated in the electric charge accumulation section and causes a threshold voltage to shift to a positive direction from a depletion type into an enhancement type.

14. The semiconductor device according to claim 4, wherein
a gate length of the first insulated gate field-effect transistor in a direction coinciding with a direction in which the first main electrode and the second main electrode are disposed is formed to be 0.05 μm or more and 0.3 μm or less, and
a gate width in a direction intersecting the direction of the gate length is formed to be 10 μm or more and 10000 μm or less.

15. The semiconductor device according to claim 5, wherein the resistance is formed to be 100 Ω or more and 10 MΩ or less.

16. The semiconductor device according to claim 4, further comprising a power amplifier including a second insulated gate field-effect transistor formed as a depletion type.

17. The semiconductor device according to claim 16, wherein
the first insulated gate field-effect transistor and the second insulated gate field-effect transistor each include InAlN, and
a thickness of at least a portion of InAlN in the first insulated gate field-effect transistor is smaller than a thickness of InAlN in the second insulated gate field-effect transistor.

18. The semiconductor device according to claim 4, further comprising an inductive resistance that is electrically coupled in series between the external terminal and the first main electrode.

19. The semiconductor device according to claim 4, further comprising a coupling capacitor that is electrically coupled in series between the external terminal and the internal circuit.

20. The semiconductor device according to claim 4, wherein a plurality of the first insulated gate field-effect transistors is provided symmetrically.
